(19) United States
(12) Patent Application Publication
(10) Pub. No.: US 2026/0189047 A1
(43) Pub. Date: Jul. 2, 2026

(54) INTERMITTENT CHARGING AND DISCHARGING METHOD, INTERMITTENT DISCHARGING METHOD AND ELECTRONIC CIRCUIT USING INTERMITTENT CHARGING AND DISCHARGING

(71) Applicant: PowerX Semiconductor Corporation, Hsinchu County (TW)

(72) Inventors: Rui Rong WANG, Hsinchu County (TW); Yong Cyuan CHEN, Hsinchu County (TW); Chung-Kang WU, Hsinchu County (TW)

(21) Appl. No.: 19/199,413

(22) Filed: May 6, 2025

(30) Foreign Application Priority Data
Dec. 31, 2024 (TW) 113151810

(51) Int. Cl. H02J 7/00; H03K 17/16

(52) U.S. Cl. CPC H02J 7/927; H02J 7/933; H03K 17/16; H02J 2207/20

(57) ABSTRACT

The present disclosure provides an intermittent charging and discharging method, an electronic circuit using intermittent charging and discharging and an intermittent discharging method. The intermittent charging and discharging method includes: during a first period, charging a power stage circuit multiple times respectively within multiple duty-on periods of multiple consecutive pulse waves of a charging control signal, to generate multiple first charging stepped-shape segments of a rising segment of a voltage signal of the power stage circuit; and during the first period, stopping charging the power stage circuit within multiple duty-off periods of the consecutive pulse waves of the charging control signal, to generate a stopping charging horizontal segment or a first discharging stepped-shape segment between two of the first charging stepped-shape segments of the voltage signal.

### CROSS-REFERENCE TO RELATED APPLICATION

This application claims priority to Taiwan Application Serial Number 113151810, filed on Dec. 31, 2024, which is herein incorporated by reference in its entirety.

### BACKGROUND

### Field of Invention

This disclosure relates to charging and discharging, in particular to an intermittent charging and discharging method, an intermittent discharging method and an electronic circuit using intermittent charging and discharging.

### Description of Related Art

In recent years, our requirements for efficiency and electromagnetic interference are getting higher and higher due to the technology development and the awakening of environmental protection consciousness. The control of switches is vital for some applications such as communication, energy transformation, etc. Also, because the costs for materials and human resources rise, researcher's goals are always to reduce product design area and increase technical quality.

### SUMMARY

An aspect of present disclosure relates to an intermittent charging and discharging method. The intermittent charging and discharging method includes: during a first period, charging a power stage circuit multiple times respectively within a plurality of duty-on periods of a plurality of consecutive pulse waves of a charging control signal, to generate a plurality of first charging stepped-shape segments of a rising segment of a voltage signal of the power stage circuit; and during the first period, stopping charging the power stage circuit within a plurality of duty-off periods of the plurality of consecutive pulse waves of the charging control signal, to generate a stopping charging horizontal segment or a first discharging stepped-shape segment between two of the plurality of first charging stepped-shape segments of the voltage signal.

Another aspect of present disclosure relates to an intermittent discharging method. The intermittent discharging method includes: discharging a power stage circuit multiple times respectively within a plurality of duty-on periods of a plurality of consecutive pulse waves of a discharging control signal, to generate a plurality of discharging stepped-shape segments of a falling segment in a voltage signal of the power stage circuit; and stopping discharging the power stage circuit within a plurality of duty-off periods of the plurality of consecutive pulse waves of the discharging control signal, to generate a stopping discharging horizontal segment or a charging stepped-shape segment between two of the plurality of discharging stepped-shape segments of the voltage signal.

Another aspect of present disclosure relates to an electronic circuit using intermittent charging and discharging. The electronic circuit using intermittent charging and discharging includes a control circuit, a power stage circuit and a charging circuit. The control circuit is configured to generate a charging control signal. The power stage circuit is configured to receive a voltage signal. The charging circuit is coupled to the power stage circuit and the control circuit, and is controlled by the control circuit according to the charging control signal. During a first period, the control circuit controls the charging circuit to charge the power stage circuit multiple times respectively within a plurality of duty-on periods of a plurality of consecutive pulse waves of the charging control signal, to generate a plurality of first charging stepped-shape segments of a rising segment of the voltage signal. During the first period, the control circuit controls the charging circuit to stop charging the power stage circuit within a plurality of duty-off periods of the plurality of consecutive pulse waves of the charging control signal, to generate a stopping charging horizontal segment or a first discharging stepped-shape segment between two of the plurality of first charging stepped-shape segments of the voltage signal.

### BRIEF DESCRIPTION OF THE DRAWINGS

The present disclosure can be more fully understood by reading the following detailed description of the embodiment, with reference made to the accompanying drawings as follows:

FIG. 1 is a block diagram of an electronic circuit using intermittent charging in accordance with a first embodiment of the present disclosure;

FIG. 2 is a flow diagram of an intermittent charging method in accordance with the first embodiment of the present disclosure;

FIG. 3 is a block diagram of an electronic circuit using intermittent charging and discharging in accordance with a second embodiment of the present disclosure;

FIG. 4 is a flow diagram of an intermittent discharging method in accordance with the second embodiment of the present disclosure;

FIG. 5 is a circuit diagram of an electronic circuit using intermittent charging and discharging in accordance with a third embodiment of the present disclosure;

FIGS. 6-11 are waveform diagrams of main signals of electronic circuits in accordance with fourth to ninth embodiments of the present disclosure;

FIG. 12 is a circuit diagram of a control circuit of an electronic circuit using intermittent charging and discharging in accordance with a tenth embodiment of the present disclosure;

FIG. 13 is a waveform diagram of a charging control signal and other main signals of the electronic circuit in accordance with the tenth embodiment of the present disclosure;

FIG. 14 is a waveform diagram of a discharging control signal and other main signals of the electronic circuit in accordance with the tenth embodiment of the present disclosure;

FIG. 15 is a circuit diagram of an electronic circuit using intermittent charging and discharging in accordance with an eleventh embodiment of the present disclosure; and

FIG. 16 is a waveform diagram of main signals of an electronic circuit in accordance with a twelfth embodiment of the present disclosure.

### DETAILED DESCRIPTION

The embodiments are described in detail below with reference to the appended drawings to better understand the aspects of the present application. However, the provided embodiments are not intended to limit the scope of the disclosure, and the description of the structural operation is not intended to limit the order in which they are performed. Any device that has been recombined by components and produces an equivalent function is within the scope covered by the disclosure.

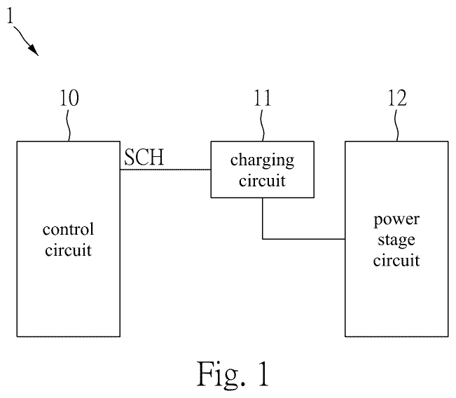

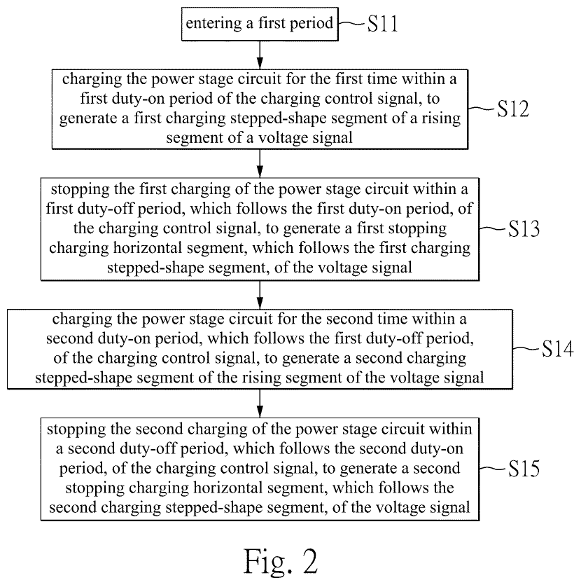

FIG. 1 is a block diagram of an electronic circuit using intermittent charging in accordance with a first embodiment of the present disclosure. FIG. 2 is a flow diagram of an intermittent charging method in accordance with the first embodiment of the present disclosure. Referring to FIGS. 1 and 2, the intermittent charging method of the present disclosure includes multiple intermittent charging steps S11-S15 as shown in FIG. 2, and can be executed by the electronic circuit using intermittent charging of the present disclosure (e.g., an electronic circuit 1 of FIG. 1). As shown in FIG. 1, the electronic circuit 1 includes a control circuit 10, a charging circuit 11 and a power stage circuit 12. The control circuit 10 generates a charging control signal SCH. The charging circuit 11 is coupled to the control circuit 10 to receive the charging control signal SCH. In addition, the charging circuit 11 is further coupled to the power stage circuit 12. The control circuit 10 is operated during multiple switching periods to control the power stage circuit 12. The operations of the electronic circuit 1 during each switching period would be described in detail below with reference to FIGS. 1 and 2.

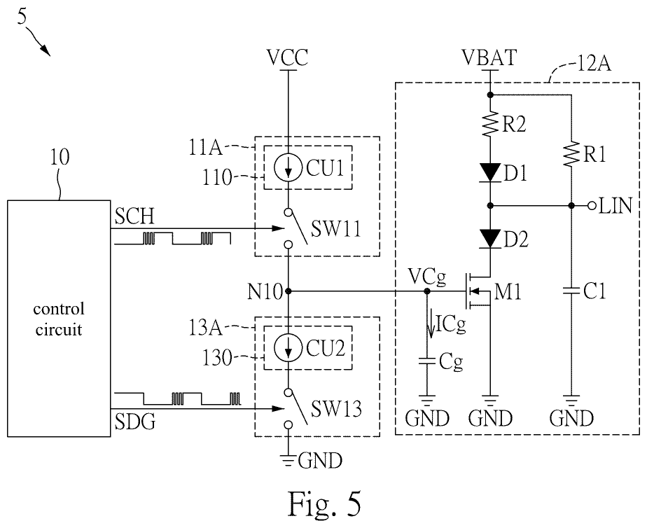

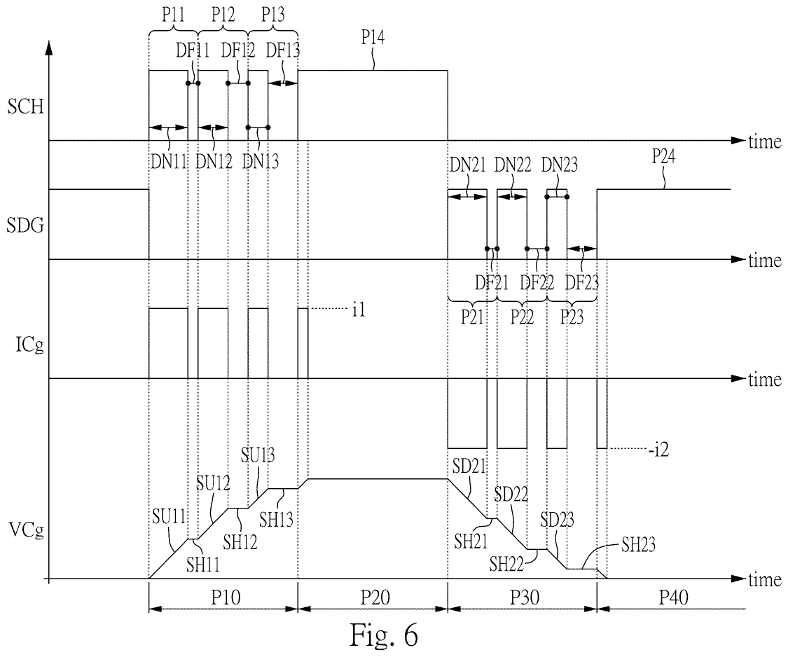

In step S11, the electronic circuit 1 enters a first period of a switching period (e.g., a charging period P10 of FIG. 6), and executes steps S12-S15 during the first period. During the first period, the charging control signal SCH has a plurality of consecutive pulse waves (i.e., having at least two pulse waves, such as pulse waves P11 and P12 of FIG. 6), and each pulse wave includes a duty-on period (e.g., duty-on periods DN11 and DN12 of FIG. 6) and a duty-off period (e.g., duty-off periods DF11 and DF12 of FIG. 6). In step S12, the control circuit 10, by the charging control signal SCH, controls the charging circuit 11 to charge the power stage circuit 12 for the first time. In particular, in step S12, the control circuit 10 controls the charging circuit 11 to charge the power stage circuit 12 for the first time within a first duty-on period (e.g., the duty-on period DN11 of the pulse wave P11 of FIG. 6) of the charging control signal SCH, to generate a first charging stepped-shape segment (e.g., a charging stepped-shape segment SU11 of FIG. 6) of a rising segment of a voltage signal (e.g., a gate capacitor voltage signal VCg of FIG. 5). In this embodiment, the voltage signal is received by the power stage circuit 12. In step S13, the control circuit 10, by the charging control signal SCH, controls the charging circuit 11 to stop the first charging of the power stage circuit 12. In particular, in step S13, the control circuit 10 controls the charging circuit 11 to stop the first charging of the power stage circuit 12 within a first duty-off period (e.g., the duty-off period DF11 of the pulse wave P11 of FIG. 6), which follows the first duty-on period, of the charging control signal SCH, to generate a first stopping charging horizontal segment (e.g., a stopping charging horizontal segment SH11 of FIG. 6), which follows the first charging stepped-shape segment, of the voltage signal.

Then, in step S14, the control circuit 10 controls the charging circuit 11 to charge the power stage circuit 12 for the second time within a second duty-on period (e.g., the duty-on period DN12 of the pulse wave P12 of FIG. 6), which follows the first duty-off period, of the charging control signal SCH, to generate a second charging stepped-shape segment (e.g., a charging stepped-shape segment SU12 of FIG. 6) of the rising segment of the voltage signal. Afterwards, in step S15, the control circuit 10 controls the charging circuit 11 to stop the second charging of the power stage circuit 12 within a second duty-off period (e.g., the duty-off period DF12 of the pulse wave P12 of FIG. 6), which follows the second duty-on period, of the charging control signal SCH, to generate a second stopping charging horizontal segment (e.g., a stopping charging horizontal segment SH12 of FIG. 6), which follows the second charging stepped-shape segment, of the voltage signal.

In the above embodiment, the intermittent charging method of the present disclosure is described by taking the first and second duty-on periods and the first and second duty-off periods of the charging control signal SCH during the first period as example (that is, by taking the charging control signal SCH having two consecutive pulse waves as example). When the charging control signal SCH includes three or more than three consecutive pulse waves (e.g., the pulse waves P11-P13 of FIG. 6) during the first period, the electronic circuit 1 can execute operations similar to steps S12 and S13 (and/or steps S14 and S15) after step S15, to again perform at least one charging operation and at least one stopping charging operation on the power stage circuit 12. That is to say, in the intermittent charging method of the present disclosure, after the power stage circuit 12 is charged for a period of time, the charging of the power stage circuit 12 is stopped within a rest period, so as to achieve the intermittent/multistage charging of the power stage circuit 12.

The conventional charging method utilizes the single continuous charging, to charge a voltage of a power stage circuit from a valley level or an initial low level directly to a peak level or a preset high level. However, the present disclosure applies the intermittent/multistage charging to the power stage circuit 12, to charge the voltage signal of the power stage circuit 12 to different voltage levels during multiple charging periods, respectively. Thus, the voltage signal of the power stage circuit 12 is increased in stages until being increased to the peak level or the preset high level. In comparison with the conventional charging method, the intermittent charging method of the present disclosure can set a charging time length and a charging rest time length (i.e., a time length of stopping charging) of each stage according to the requirements of applications, which greatly improves the accuracy of the charging control to flexibly control the charging state of the power stage circuit 12.

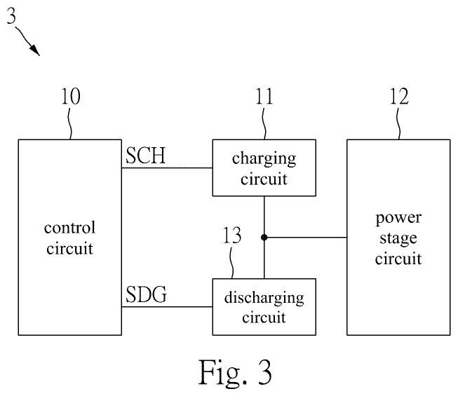

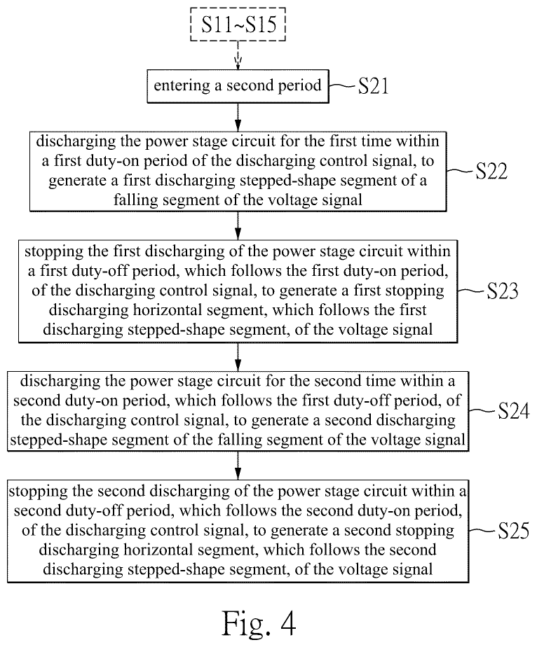

FIG. 3 is a block diagram of an electronic circuit using intermittent charging and discharging in accordance with a second embodiment of the present disclosure. FIG. 4 is a flow diagram of an intermittent discharging method in accordance with the second embodiment of the present disclosure. As shown in FIG. 4, the intermittent discharging method of the present disclosure includes multiple steps S21-S25. As shown in FIG. 3, in the second embodiment, an electronic circuit 3 using intermittent charging and discharging includes not only the control circuit 10, the charging circuit 11 and the power stage circuit 12, but also a discharging circuit 13. Steps S21-S25 can be executed by the control circuit 10, the power stage circuit 12 and the discharging circuit 13 of the electronic circuit 3. Referring to FIG. 3, the control circuit 10 generates not only the charging control signal SCH, but also a discharging control signal SDG. The discharging circuit 13 is coupled to the control circuit 10 to receive the discharging control signal SDG. In addition, the discharging circuit 13 is further coupled to the power stage circuit 12. The control circuit 10 is operated during multiple switching periods to control the power stage circuit 12 by the charging control signal SCH and the discharging control signal SDG. The operations of the electronic circuit 3 during each switching period would be described in detail below with reference to FIGS. 3 and 4.

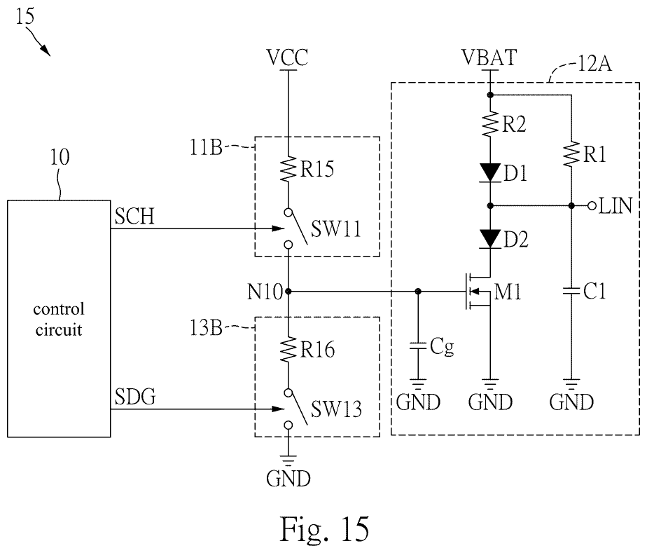

In some embodiments, steps S21-S25 follow steps S11-S15 (which are represented by a block in broken lines in FIG. 4) of FIG. 2, so that step S11-S15 and steps S21-S25 are used as steps of an intermittent charging and discharging method of the present disclosure. The intermittent charging and discharging method of the present disclosure is executed by the electronic circuit using intermittent charging and discharging (e.g., the electronic circuit 3 of FIG. 3, an electronic circuit 5 of FIG. 5, an electronic circuit 15 of FIG. 15, etc.) of the present disclosure.

Referring to FIGS. 3 and 4, in step S21, the electronic circuit 3 enters a second period of a switching period (e.g., a discharging period P30 of FIG. 6), and executes steps S22-S25 during the second period. During the second period, the discharging control signal SDG has a plurality of consecutive pulse waves (i.e., having at least two pulse waves, such as pulse waves P21 and P22 of FIG. 6), and each pulse wave includes a duty-on period (e.g., duty-on periods DN21 and DN22 of FIG. 6) and a duty-off period (e.g., duty-off periods DF21 and DF22 of FIG. 6). In the embodiments where steps S21-S25 follow steps S11-S15, the second period is after the first period on a time axis.

In step S22, the control circuit 10, by the discharging control signal SDG, controls the discharging circuit 13 to discharge the power stage circuit 12 for the first time. In particular, in step S22, the control circuit 10 controls the discharging circuit 13 to discharge the power stage circuit 12 for the first time within a first duty-on period (e.g., the duty-on period DN21 of the pulse wave P21 of FIG. 6) of the discharging control signal SDG, to generate a first discharging stepped-shape segment (e.g., a discharging stepped-shape segment SD21 of FIG. 6) of a falling segment of the voltage signal. In step S23, the control circuit 10, by the discharging control signal SDG, controls the discharging circuit 13 to stop the first discharging of the power stage circuit 12. In particular, in step S23, the control circuit 10 controls the discharging circuit 13 to stop the first discharging of the power stage circuit 12 within a first duty-off period (e.g., the duty-off period DF21 of the pulse wave P21 of FIG. 6), which follows the first duty-on period, of the discharging control signal SDG, to generate a first stopping discharging horizontal segment (e.g., a stopping discharging horizontal segment SH21 of FIG. 6), which follows the first discharging stepped-shape segment, of the voltage signal.

Then, in step S24, the control circuit 10 controls the discharging circuit 13 to discharge the power stage circuit 12 for the second time within a second duty-on period (e.g., the duty-on period DN22 of the pulse wave P22 of FIG. 6), which follows the first duty-off period, of the discharging control signal SDG, to generate a second discharging stepped-shape segment (e.g., a discharging stepped-shape segment SD22 of FIG. 6) of the falling segment of the voltage signal. Afterwards, in step S25, the control circuit 10 controls the discharging circuit 13 to stop the second discharging of the power stage circuit 12 within a second duty-off period (e.g., the duty-off period DF22 of the pulse wave P22 of FIG. 6), which follows the second duty-on period, of the discharging control signal SDG, to generate a second stopping discharging horizontal segment (e.g., a stopping discharging horizontal segment SH22 of FIG. 6), which follows the second discharging stepped-shape segment, of the voltage signal.

In the above embodiment, the intermittent discharging method of the present disclosure is described by taking the first and second duty-on periods and the first and second duty-off periods of the discharging control signal SDG during the second period as example (that is, by taking the discharging control signal SDG having two consecutive pulse waves as example). When the discharging control signal SDG includes three or more than three consecutive pulse waves (e.g., the pulse waves P21-P23 of FIG. 6) during the second period, the electronic circuit 3 can execute operations similar to steps S22 and S23 (and/or steps S24 and S25) after step S25, to again perform at least one discharging and at least one stopping discharging on the power stage circuit 12. Notably, in the intermittent discharging method of the present disclosure, after the power stage circuit 12 is discharged for a period of time, the discharging of the power stage circuit 12 is stopped within a rest period, so as to achieve the intermittent/multistage discharging of the power stage circuit 12.

The conventional discharging method utilizes the single continuous discharging, to discharge a voltage of a power stage circuit from a peak level or an initial high level directly to a valley level or a preset low level. However, the present disclosure applies the intermittent/multistage discharging to the power stage circuit 12, to discharge the voltage signal of the power stage circuit to different voltage levels during multiple discharging periods, respectively. Thus, the voltage signal of the power stage circuit is decreased in stages until being decreased to the valley level or the preset low level. In comparison with the conventional discharging method, the intermittent discharging method of the present disclosure can set a discharging time length and a discharging rest time length (i.e., a time length of stopping discharging) of each stage according to the requirements of applications, which greatly improves the accuracy of the discharging control to flexibly control the discharging state of the power stage circuit 12.

In comparison with the conventional charging and discharging method, the control circuit 10, which is described in the intermittent charging and discharging method of the present disclosure, accurately controls the level of the voltage signal by intermittently controlling enable times of the charging circuit 11 and/or the discharging circuit 13, so as to control a switching speed at which the power stage circuit 12 is switched to a different operation state. For example, the speed at which the voltage signal rises from the valley level or the initial low level to the peak level or the preset high level (which would be regarded as a rising speed of the voltage signal in the following paragraphs) is accurately controlled, and/or the speed at which the voltage signal falls from the peak level or the initial high level to the valley level or the preset low level (which would be regarded as a falling speed of the voltage signal in the following paragraphs) is accurately controlled. The control circuit 10 can select appropriate intermittent switching strategy according to selected characteristics of the power stage circuit 12, such as turn-on curve, parasitic parameter, etc., to control the rising and/or falling speed of the voltage signal.

If only a simple setting for the rising and/or falling speed of the voltage signal is required, a constant frequency control at relative low frequency can be selected. The noise is relative low in operations with constant frequency. If an accurate change in the voltage level of the voltage signal is required, variable frequency control can be adopted, to provide efficient and instant responses by frequency variations.

FIG. 5 is a circuit diagram of an electronic circuit using intermittent charging and discharging in accordance with a third embodiment of the present disclosure. As shown in FIG. 5, an electronic circuit 5 using intermittent charging and discharging of the present disclosure includes a control circuit 10, a charging circuit 11A, a discharging circuit 13A and a power stage circuit 12A. The control circuit 10 generates a charging control signal SCH and a discharging control signal SDG. In FIG. 5, the pattern of the pulse waves of the charging control signal SCH and the pattern of the pulse waves of the discharging control signal SDG are only examples for illustrative purpose, and are not intended to limit the present disclosure. Referring to FIGS. 5 and 3 together, the charging circuit 11A, the discharging circuit 13A and the power stage circuit 12A of FIG. 5 are respective implementations of the charging circuit 11, the discharging circuit 13 and the power stage circuit 12 of FIG. 3. The charging circuit 11A includes a charging-side current source circuit 110 (which is regarded as the current source circuit 110 below) and a charging switch SW11. In this embodiment, the current source circuit 110 includes a charging-side current source CU1 (which is regarded as the current source CU1 below). An input terminal of the current source CU1 is coupled to a power voltage VCC, and an output terminal thereof is coupled to a first terminal of the charging switch SW11. A second terminal of the charging switch SW11 is coupled to an input terminal of the power stage circuit 12A at a node N10. A control terminal of the charging switch SW11 is coupled to the control circuit 10 to receive the charging control signal SCH.

The discharging circuit 13A includes a discharging-side current source circuit 130 (which is regarded as the current source circuit 130 below) and a discharging switch SW13. In this embodiment, the current source circuit 130 includes a discharging-side current source CU2 (which is regarded as the current source CU2 below). An input terminal of the current source CU2 is coupled to the input terminal of the power stage circuit 12A at the node N10, and an output terminal thereof is coupled to a first terminal of the discharging switch SW13. A second terminal of the discharging switch SW13 is coupled to a ground terminal GND. A control terminal of the discharging switch SW13 is coupled to the control circuit 10 to receive the discharging control signal SDG.

Referring to FIG. 5, the power stage circuit 12A mainly includes a capacitor Cg and a power transistor M1. In addition, according to a system architecture where the electronic circuit 5 is applied, the power stage circuit 12A can further include other electronic components. For example, when the electronic circuit 5 is applied to the system architecture of Local Interconnect Network (LIN), the power stage circuit 12A can further include an upper side diode D1, a lower side diode D2, resistors R1 and R2 and a capacitor C1. A first terminal of the capacitor Cg and a control terminal of the power transistor M1 are coupled to the input terminal of the power stage circuit 12A at the node N10, and further to the second terminal of the charging switch SW11 and the input terminal of the current source CU2 through the input terminal of the power stage circuit 12A. A second terminal of the capacitor Cg is coupled to the ground terminal GND. A first terminal of the power transistor M1 is coupled to a cathode of the lower side diode D2, and a second terminal thereof is coupled to the ground terminal GND. A cathode of the upper side diode D1 is coupled to an anode of the lower side diode D2. A first terminal of the resistor R2 and a first terminal of the resistor R1 are coupled to a power voltage VBAT. A second terminal of the resistor R2 is coupled to an anode of the upper side diode D1. A second terminal of the resistor R1, the cathode of the upper side diode D1, the anode of the lower side diode D2 and a first terminal of the capacitor C1 are coupled to an output terminal LIN of the power stage circuit 12A. A second terminal of the capacitor C1 is coupled to the ground terminal GND. In this embodiment, the power transistor M1 is implemented by an N-type field effect transistor. Thus, the control terminal, the first terminal and the second terminal of the power transistor M1 are a gate terminal, a drain terminal and a source terminal of the N-type field effect transistor, respectively.

When the charging switch SW11 is turned on according to the charging control signal SCH, the current source CU1 provides a charging current flowing to the capacitor Cg through the turned-on charging switch SW11, to charge the capacitor Cg, such that a voltage level of the gate capacitor voltage signal VCg at the first terminal of the capacitor Cg (i.e., the input terminal of the power stage circuit 12A) is gradually increased. When the charging switch SW11 is turned off according to the charging control signal SCH, the current source circuit 110 stops providing the charging current to the capacitor Cg, such that the charging circuit 11A stops charging the capacitor Cg as well as the voltage level of the gate capacitor voltage signal VCg is stopped being increased. For example, the charging switch SW11 is turned on during the duty-on periods of the charging control signal SCH, and is turned off during the duty-off periods of the charging control signal SCH. The duty-on periods of the consecutive pulse waves of the charging control signal SCH are determined according to a voltage difference between the control terminal and the second terminal of the power transistor M1, that is, are determined by a real gate source voltage (VGS) of the power transistor M1.

When the discharging switch SW13 is turned on according to the discharging control signal SDG, the current source CU2 provides a discharging current flowing to the ground terminal GND through the turned-on discharging switch SW13, to discharge the capacitor Cg of the power stage circuit 12A, such that the voltage level of the gate capacitor voltage signal VCg is gradually decreased. When the discharging switch SW13 is turned off according to the discharging control signal SDG, the current source circuit 130 stops providing the discharging current to the ground terminal GND, such that the discharging circuit 13A stops discharging the capacitor Cg as well as the voltage level of the gate capacitor voltage signal VCg is stopped being decreased. For example, the discharging switch SW13 is turned on during the duty-on periods of the discharging control signal SDG, and is turned off during the duty-off periods of the discharging control signal SDG. The duty-on periods of the consecutive pulse waves of the discharging control signal SDG are determined according to the real gate source voltage (VGS) of the power transistor M1.

According to the above descriptions, the present disclosure controls the charging switch SW11 to be turned on intermittently, so that the charging current outputted by the current source CU1 is gradually released to the capacitor Cg within discontinuous periods to increase the voltage of the control terminal of the power transistor M1 (i.e., the voltage level of the gate capacitor voltage signal VCg), thereby controlling the turn-on speed of the power transistor M1. Similarly, the present disclosure controls the discharging switch SW13 to be turned on intermittently, so that the capacitor Cg is gradually discharged within discontinuous periods to decrease the voltage of the control terminal of the power transistor M1, thereby controlling the turn-off speed of the power transistor M1. The power transistor M1 is operated according to the gate capacitor voltage signal VCg, so as to control a speed of change (e.g., rising or falling) in a level of an output voltage at the output terminal LIN of the power stage circuit 12A.

FIG. 6 is a waveform diagram of main signals of an electronic circuit in accordance with a fourth embodiment of the present disclosure. The pattern of the pulse waves of the charging control signal SCH of FIG. 6 is an illustrative example of the charging control signal SCH of each of FIGS. 1, 3, 5 and 15, and the pattern of the pulse waves of the discharging control signal SDG of FIG. 6 is an illustrative example of the discharging control signal SDG of each of FIGS. 3, 5 and 15.

As shown in FIG. 6, the pulse waves of the charging control signal SCH can be different from each other in the frequency, the duty-on period, the duty-off period, or a combination thereof, and the pulse waves of the discharging control signal SDG can be different from each other in the frequency, the duty-on period, the duty-off period, or a combination thereof. However, these are only examples for illustrative purpose, and the present disclosure is not limited herein. During the switching periods, the control circuit 10 controls the power stage circuit 12A by the charging control signal SCH and the discharging control signal SDG. Referring to FIG. 6, the electronic circuit 5 can be operated during consecutive periods P10, P20, P30 and P40 in one switching period. In the following paragraphs, the charging and discharging operations of a power stage circuit of the present disclosure during a switching period is described through the electronic circuit 5 of FIG. 5 with reference to the main signals of FIG. 6. During the charging period P10 of the power stage circuit 12A, the charging control signal SCH has multiple consecutive pulse waves P11-P13, and each pulse wave includes a duty-on period and a duty-off period. Thus, the pulse waves P11-P13 include the duty-on periods DN11-DN13, respectively, and include the duty-off periods DF11-DF13, respectively. In addition, during the charging period P10 and the followed maintaining period P20, the discharging control signal SDG is maintained at a low voltage level without any pulse wave.

Referring to FIGS. 5 and 6, during the charging period P10, the discharging switch SW13 is constantly turned off due to the discharging control signal SDG at the low voltage level, to cut off a discharging path between the node N10 and the ground terminal GND. In addition, during the charging period P10, the control circuit 10 turns the charging switch SW11 on within the duty-on periods DN11-DN13 of the charging control signal SCH, respectively, so that the charging circuit 11A, by the current source circuit 110, provides the charging current having a charging current value i1 to the power stage circuit 12A. In such way, during the duty-on periods DN11-DN13, the charging current from the current source circuit 110 is provided to the first terminal of the capacitor Cg to charge the capacitor Cg multiple times, so as to generate multiple charging stepped-shape segments SU11-SU13 in a gradually rising segment of the gate capacitor voltage signal VCg. Referring to FIGS. 5 and 6, during the duty-on periods DN11-DN13, a gate current ICg of the capacitor Cg has the charging current value i1, in which the charging current value i1 is a positive value representing the gate current ICg flows towards the capacitor Cg (that is, to charge the capacitor Cg). During the charging period P10, the control circuit 10 turns the charging switch SW11 off within the duty-off periods DF11-DF13 of the charging control signal SCH, so that the charging circuit 11A stops charging the power stage circuit 12A with the charging current. Thus, during the duty-off periods DF11-DF13, the gate capacitor voltage signal VCg is stopped being increased, and multiple stopping charging horizontal segments SH11-SH13 are generated in the rising segment. After the charging period P10, the electronic circuit 5 enters and is operated during the maintaining period P20.

During the maintaining period P20, the control circuit 10 outputs the charging control signal SCH having a pulse wave P14. In this embodiment, a time length of a duty-on period of the pulse wave P14 (corresponding to the width of the pulse wave P14) is equal to a time length of the maintaining period P20, and the pulse wave P14 does not have duty-off period. Referring to FIGS. 5 and 6, during the maintaining period P20, the charging switch SW11 is turned on according to the pulse wave P14, and the charging circuit 11A, by the current source circuit 110, provides the charging current to the first terminal of the capacitor Cg, so that the capacitor Cg is charged again, and the voltage level of the gate capacitor voltage signal VCg is increased again. When the voltage level of the gate capacitor voltage signal VCg is increased to the peak level or the preset high level, the gate current ICg becomes zero, and the charging switch SW11 is constantly turned on according to the pulse wave P14 to maintain the gate capacitor voltage signal VCg at the peak level or the preset high level. At a time point when the maintaining period P20 is ended, the charging control signal SCH is switched to the low voltage level (that is, the pulse wave P14 is ended). After the maintaining period P20, the electronic circuit 5 enters the discharging period P30 of the power stage circuit 12A and is operated during the discharging period P30.

As shown in FIG. 6, during the discharging period P30, the discharging control signal SDG has multiple consecutive pulse waves P21-P23, and each pulse wave includes a duty-on period and a duty-off period. Thus, the pulse waves P21-P23 includes the duty-on periods DN21-DN23, respectively, and includes the duty-off periods DF21-DF23, respectively.

Referring to FIGS. 5 and 6, during the discharging period P30 and the followed maintaining period P40, the charging control signal SCH is switched to and maintained at the low voltage level. Thus, the charging switch SW11 is constantly turned off, to cut off a charging path between the power voltage VCC and the node N10. In addition, during the discharging period P30, the control circuit 10 turns the discharging switch SW13 on within the duty-on periods DN21-DN23 of the discharging control signal SDG, respectively, so that the capacitor Cg is discharged by the current source CU2 providing the discharging current. Thus, multiple discharging stepped-shape segments SD21-SD23 are generated in a gradually falling segment of the gate capacitor voltage signal VCg. Referring to FIGS. 5 and 6, during the duty-on periods DN21-DN23, the gate current ICg of the capacitor Cg has a discharging current value −i2, in which the discharging current value −i2 is a negative value representing the gate current ICg flows out of the capacitor Cg (that is, to discharge the capacitor Cg). During the discharging period P30, the control circuit 10 turns the discharging switch SW13 off within the duty-off periods DF21-DF23 of the discharging control signal SDG, so that the discharging circuit 13A stops discharging the capacitor Cg. Thus, during the duty-off periods DF21-DF23, the gate capacitor voltage signal VCg is stopped being decreased, and multiple stopping discharging horizontal segments SH21-SH23 are generated in the falling segment. After the discharging period P30, the electronic circuit 5 enters the maintaining period P40 and is operated during the maintaining period P40.

During the maintaining period P40, the control circuit 10 outputs the discharging control signal SDG having a pulse wave P24. In this embodiment, a time length of a duty-on period of the pulse wave P24 (corresponding to the width of the pulse wave P24) is equal to a time length of the maintaining period P40. Referring to FIGS. 5 and 6, during the maintaining period P40, the discharging switch SW13 is turned on according to the pulse wave P24, and the discharging circuit 13A provides the discharging current by the current source CU2, so that the capacitor Cg is discharged again, and the voltage level of the gate capacitor voltage signal VCg is decreased again. When the voltage level of the gate capacitor voltage signal VCg is decreased to the valley level or the preset low level, the gate current ICg becomes zero, and the discharging switch SW13 is constantly turned on according to the pulse wave P24 to maintain the gate capacitor voltage signal VCg at the valley level or the preset low level. At a time point when the maintaining period P40 is ended, the discharging control signal SDG is switched to the low voltage level (that is, the pulse wave P24 is ended). After the maintaining period P40, the electronic circuit 5 enters the charging period P10 of the next switching period and is operated during the charging period P10.

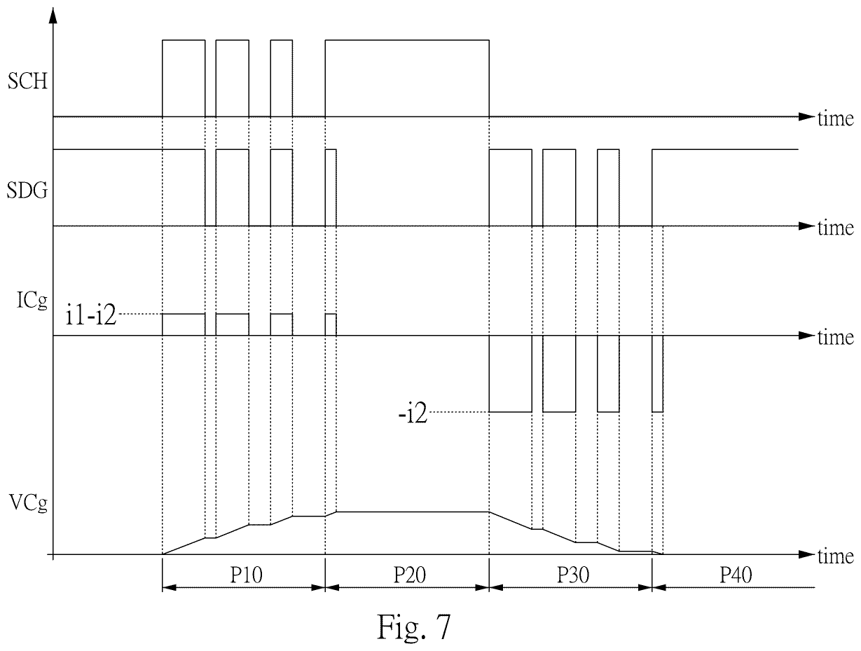

FIG. 7 is a waveform diagram of main signals of an electronic circuit in accordance with a fifth embodiment of the present disclosure. The pattern of the pulse waves of the charging control signal SCH of FIG. 7 is another illustrative example of the charging control signal SCH of each of FIGS. 1, 3, 5 and 15, and the pattern of the pulse waves of the discharging control signal SDG of FIG. 7 is another illustrative example of the discharging control signal SDG of each of FIGS. 3, 5 and 15.

From a comparison of FIGS. 6 and 7, one difference between FIGS. 6 and 7 is that the pattern of the pulse waves of the discharging control signal SDG is the same as the pattern of the pulse waves of the charging control signal SCH during the charging period P10 in FIG. 7. According to the operations of controlling the charging circuit 11A and the discharging circuit 13A in the above embodiments, the charging switch SW11 is turned on during the duty-on periods of the charging control signal SCH, and the discharging switch SW13 is turned on during the duty-on periods of the discharging control signal SDG. It is assumed that the charging current value i1 is greater than the discharging current value i2. During the charging period P10 of FIG. 7, the charging switch SW11 is turned on while the discharging switch SW13 is turned on, so that the current source circuit 110 provides the charging current to the first terminal of the capacitor Cg while the capacitor Cg is discharged by the current source CU2 providing the discharging current. As shown in FIG. 7, in each charging stepped-shape segment of the rising segment of the gate capacitor voltage signal VCg, the capacitor Cg is charged according to a current difference value between the charging current value i1 and the discharging current value i2 (i.e., the gate current ICg, ICg=i1−i2 (positive value)). In comparison to FIG. 6, the gate capacitor voltage signal VCg of FIG. 7 is slowly increased from the valley level or the initial low level to the peak level or the preset high level in the rising segment. According to the above embodiments, in the rising segment of the gate capacitor voltage signal VCg (i.e., during the charging period P10), the gate current ICg with the charging current value i1 or the current difference value (ICg=i1−i2) is appropriately utilized to charge the capacitor Cg, thereby improving the control accuracy of the turn-on speed of the power stage circuit 12A.

It is assumed that the discharging current value i2 is greater than the charging current value i1. According to another embodiment, during the discharging period P30, the charging switch SW11 is turned on while the discharging switch SW13 is turned on, so that the current source circuit 110 provides the charging current to the first terminal of the capacitor Cg while the capacitor Cg is discharged by the current source CU2 providing the discharging current. In the discharging stepped-shape segment of the falling segment of the gate capacitor voltage signal VCg, the capacitor Cg is discharged according to the current difference value between the charging current value i1 and the discharging current value i2 (ICg=i1−i2 (negative value)). In comparison to FIG. 6, the gate capacitor voltage signal VCg of this embodiment is slowly decreased from the peak level or the initial high level to the valley level or the preset low level in the falling segment. According to the above embodiments, in the falling segment of the gate capacitor voltage signal VCg (i.e., during the discharging period P30), the gate current ICg with the charging current value i2 or the current difference value (ICg=i1−i2) is appropriately utilized to discharge the capacitor Cg, thereby improving the control accuracy of the turn-off speed of the power stage circuit 12A.

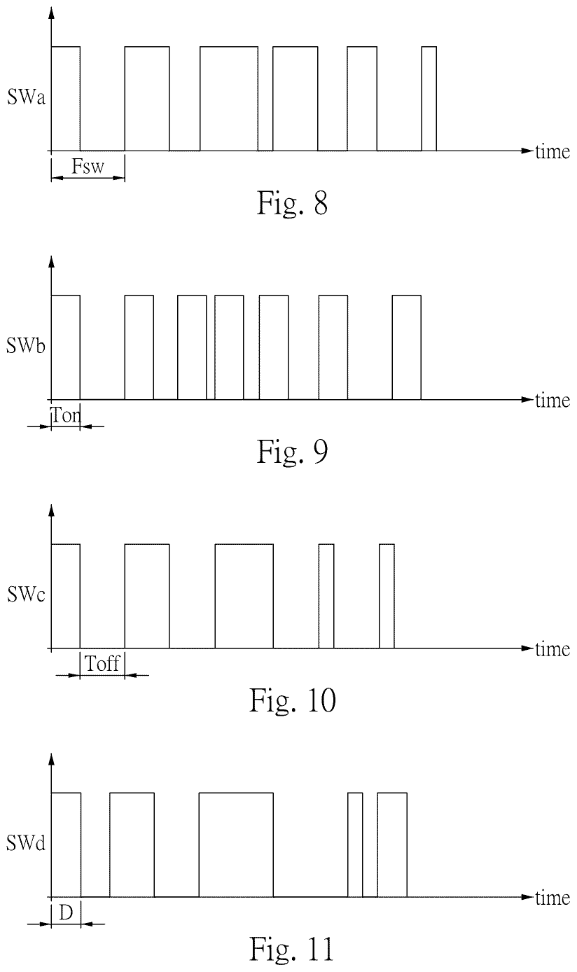

FIGS. 8-11 are waveform diagrams of main signals of electronic circuits in accordance with sixth to ninth embodiments of the present disclosure. The pattern of the pulse waves of the charging control signal SCH generated by the control circuit 10 of each of FIGS. 1, 3, 5 and 15 and/or the pattern of the pulse waves of the discharging control signal SDG generated by the control circuit 10 of each of FIGS. 3, 5 and 15 can be the same as the pattern of pulse waves of a control signal SWa as shown in FIG. 8, a control signal SWb as shown in FIG. 9, a control signal SWc as shown in FIG. 10, or a control signal SWd as shown in FIG. 11. Referring FIG. 8, the pulse waves of the control signal SWa have the same frequency, such as a fixed frequency Fsw. Referring FIG. 9, the pulse waves of the control signal SWb have the same duty-on period, such as a fixed turn-on time Ton. Referring FIG. 10, the pulse waves of the control signal SWc have the same duty-off period, such as a fixed turn-off time Toff. Referring FIG. 11, the pulse waves of the control signal SWd have the same duty cycle D. Each of the above-described pulse-wave patterns is an example for illustrative purpose, and the present disclosure is not limited herein.

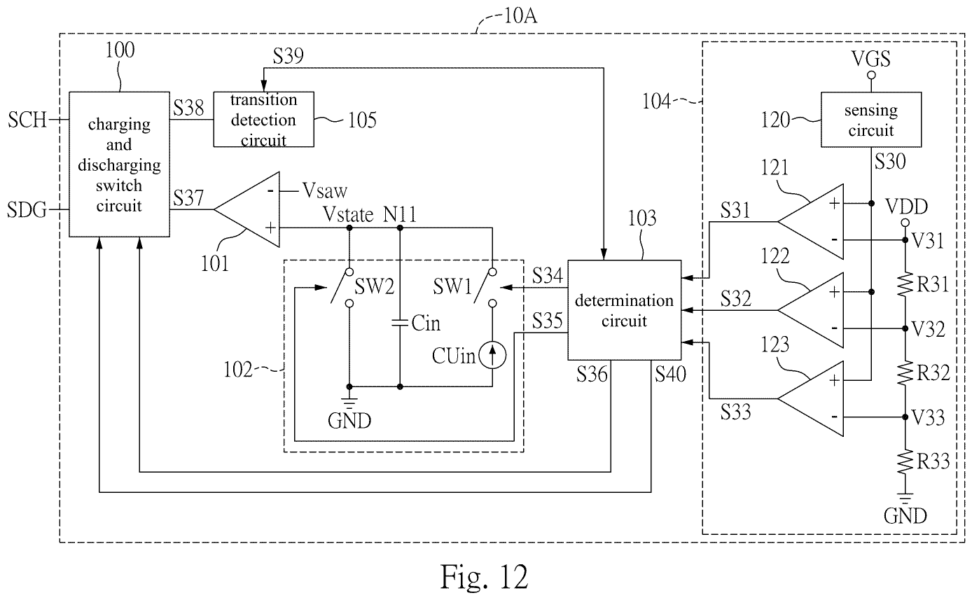

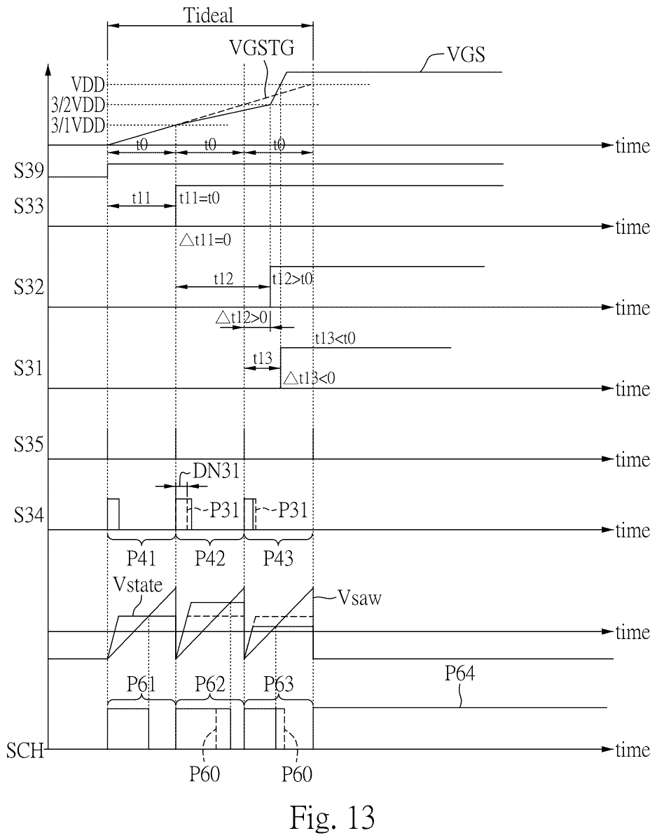

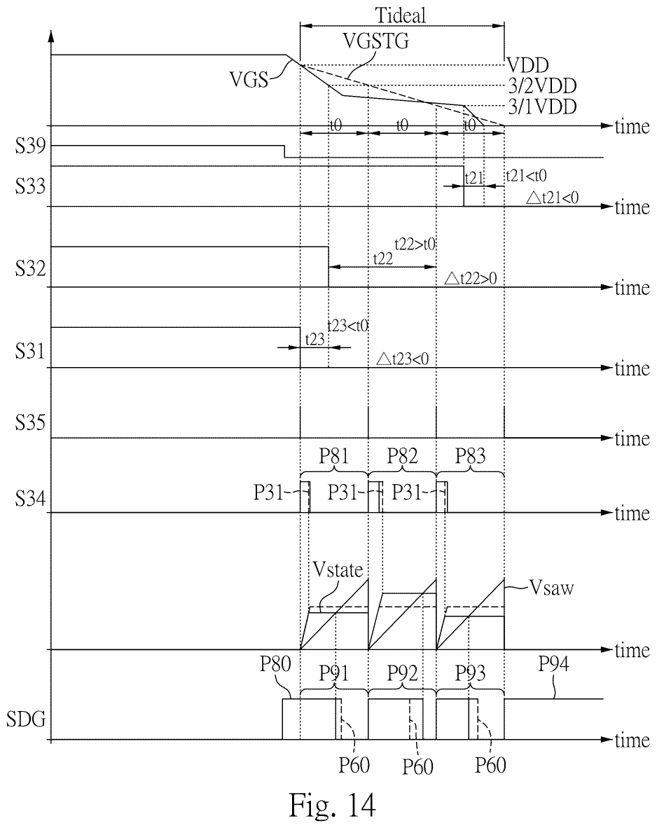

FIG. 12 is a circuit diagram of a control circuit of an electronic circuit using intermittent charging and discharging in accordance with a tenth embodiment of the present disclosure. FIG. 13 is a waveform diagram of other main signals and a charging control signal of the electronic circuit during a switching period in accordance with the tenth embodiment of the present disclosure. FIG. 14 is a waveform diagram of other main signals and a discharging control signal of the electronic circuit during a switching period in accordance with the tenth embodiment of the present disclosure. The control circuit 10A of FIG. 12 is an implementation of the control circuit 10 of each of FIGS. 1, 3, 5 and 15 but is only an example for illustrative purpose, and the present disclosure is not limited herein. As shown in FIG. 12, the control circuit 10A includes a charging and discharging switch circuit 100, a comparator 101, a signal generation circuit 102, a determination circuit 103, a sensing comparison circuit 104 and a transition detection circuit 105. During the switching periods, the control circuit 10A controls the power stage circuit 12A by the charging control signal SCH and the discharging control signal SDG.

A sensing circuit 120 is coupled to the control terminal (gate terminal) and the second terminal (source terminal) of the power transistor M1 to sense the real voltage difference VGS between the control terminal and the second terminal, to output a sensing voltage signal S30. A voltage level of the sensing voltage signal S30 represents the real voltage difference VGS. In an embodiment, the voltage level of the sensing voltage signal S30 equals a value of the real voltage difference VGS. Multiple comparators 121-123 of the sensing comparison circuit 104 (which would be described in detail below) receive the sensing voltage signal S30 from the sensing circuit 120, and compare the sensing voltage signal S30 with multiple reference voltages V31-V33, respectively, to output multiple comparison signals S31-S33, respectively.

The determination circuit 103 is coupled to the sensing comparison circuit 104 to receive the comparison signals S31-S33, determines time differences between a time taken by the sensing voltage signal S30 to reach the respective reference voltages V31-V33 and a time threshold, and generates a trigger signal S34 according to determination results. The signal generation circuit 102 is coupled to a first output terminal of the determination circuit 103 to receive the trigger signal S34, and generates a state signal Vstate according to the trigger signal S34. In this embodiment, the signal generation circuit 102 controls a voltage level of the state signal Vstate according to the trigger signal S34. According to the above descriptions, the trigger signal S34 is generated according to a level change of the sensing voltage signal S30 (representing the real voltage difference VGS of the power transistor M1), and the signal generation circuit 102 is controlled by the trigger signal S34 to generate the state signal Vstate. Thus the state signal Vstate is determined by a change state of the real voltage difference VGS.

A first input terminal (e.g., an inverted input terminal (−)) of the comparator 101 receives a reference voltage signal Vsaw, and a second input terminal (e.g., a non-inverted input terminal (+)) thereof is coupled to the signal generation circuit 102 to receive the state signal Vstate. The comparator 101 compares the state signal Vstate and the reference voltage signal Vsaw to generate a switching signal S37 at an output terminal of the comparator 101. When the voltage level of the state signal Vstate is higher than a voltage level of the reference voltage signal Vsaw, the switching signal S37 is at a high voltage level (corresponding to a duty-on period). When the voltage level of the state signal Vstate is lower than the voltage level of the reference voltage signal Vsaw, the switching signal S37 is at the low voltage level (corresponding to a duty-off period). An input terminal of the charging and discharging switch circuit 100 is coupled to the output terminal of the comparator 101 to receive the switching signal S37. A first output terminal of the charging and discharging switch circuit 100 is used as a first output terminal of the control circuit 10A, which is coupled to an input terminal of the charging circuit 11 as shown in FIG. 1 or FIG. 3, is coupled to the charging circuit 11A as shown in FIG. 5, or is coupled to the control terminal of the charging switch SW11 included in a charging circuit 11B as shown in FIG. 15. A second output terminal of the charging and discharging switch circuit 100 is used as a second output terminal of the control circuit 10A, which is coupled to an input terminal of the discharging circuit 13 as shown in FIG. 3, is coupled to the discharging circuit 13A as shown in FIG. 5, or is coupled to the control terminal of the discharging switch SW13 included in a discharging circuit 13B as shown in FIG. 15.

Referring to FIG. 12, the sensing comparison circuit 104 can include the sensing circuit 120, the comparators 121-123 and multiple reference resistors R31-R33. In another embodiment, the sensing circuit 120 can be arranged outside the sensing comparison circuit 104. A first input terminal (e.g., a non-inverted input terminal (+)) of each of the comparators 121-123 is coupled to an output terminal of the sensing circuit 120 to receive the sensing voltage signal S30. The reference resistors R31-R33 are sequentially connected in series between a power voltage VDD and the ground terminal GND. In particular, a first terminal of the reference resistor R31 is coupled to the power voltage VDD, a second terminal of the reference resistor R31 is coupled to a first terminal of the reference resistor R32, a second terminal of the reference resistor R32 is coupled to a first terminal of the reference resistor R33, and a second terminal of the reference resistor R33 is coupled to the ground terminal GND. The reference resistors R31-R33 divide a voltage difference between the power voltage VDD and a voltage of the ground terminal GND to generate the reference voltages V31, V32 and V33.

A second input terminal (e.g., an inverted input terminal (−)) of the comparator 121 is coupled to the first terminal of the reference resistor R31 to receive the power voltage VDD as the reference voltage V31. The comparator 121 compares a voltage of the sensing voltage signal S30 and the reference voltage V31 to generate the comparison signal S31 at an output terminal of the comparator 121. A second input terminal (e.g., an inverted input terminal (−)) of the comparator 122 is coupled to a common node of the reference resistors R31 and R32 to receive the reference voltage V32 from the common node. The comparator 122 compares the voltage of the sensing voltage signal S30 and the reference voltage V32 to generate the comparison signal S32 at an output terminal of the comparator 122. A second input terminal (e.g., an inverted input terminal (−)) of the comparator 123 is coupled to a common node of the reference resistors R32 and R33 to receive the reference voltage V33 from the common node. The comparator 123 compares the voltage of the sensing voltage signal S30 and the reference voltage V33 to generate the comparison signal S33 at an output terminal of the comparator 123. The comparison signals S31-S33 are provided to the determination circuit 103.

Referring to FIG. 12, the signal generation circuit 102 can include a switch SW1, a switch SW2, an input current source CUin and an input capacitor Cin. A first terminal of the switch SW1 is coupled to the second terminal of the comparator 101 at a node N11. A first terminal of the input current source CUin is coupled to a second terminal of the switch SW1, and a second terminal thereof is coupled to the ground terminal GND. A control terminal of the switch SW1 is coupled to the first output terminal of the determination circuit 103 to receive the trigger signal S34. A first terminal of the input capacitor Cin and a first terminal of the switch SW2 are coupled to the node N11. A second terminal of the input capacitor Cin and a second terminal of the switch SW2 are coupled to the ground terminal GND. The determination circuit 103 further generates a reset signal S35. A control terminal of the switch SW2 is coupled to a second output terminal of the determination circuit 103 to receive the reset signal S35.

When the switch SW1 is turned on according to the trigger signal S34, an input current provided by the input current source CUin flows to the node N11 through the switch SW1 to charge the input capacitor Cin, so that a voltage at the first terminal of the input capacitor Cin (i.e., a voltage at the node N11) is increased. A voltage signal at the first terminal of the input capacitor Cin is used as the state signal Vstate. The determination circuit 103 enables the reset signal S35 (e.g., making the reset signal S35 has a pulse wave) to turn on the switch SW2 at every interval time (i.e., at every ideal interval time t0 of FIG. 13) which equals a time threshold, to discharge the input capacitor Cin, thereby resetting a voltage at the second input terminal of the comparator 101 (to zero voltage).

The charging and discharging switch circuit 100 uses the switching signal S37 received from the output terminal of the comparator 101 as the charging control signal SCH and/or the discharging control signal SDG. For example, the charging and discharging switch circuit 100 can determine that the switching signal S37 is used as the charging control signal SCH and/or the discharging control signal SDG according to a transition detection signal S38 received from the transition detection circuit 105, which are described in detail below.

The transition detection circuit 105 receives an indication signal S39 (from an external circuit). According to an embodiment of the present disclosure, a rising edge of the indication signal S39 represents that the gate capacitor voltage signal VCg enters the rising segment, and a falling edge of the indication signal S39 represents that the gate capacitor voltage signal VCg enters the falling segment. The transition detection circuit 105 detects at least one rising edge and at least one falling edge of the indication signal S39 to output the transition detection signal S38. According to an embodiment of the present disclosure, during a switching period, each time when the transition detection circuit 105 detects a rising edge of the indication signal S39 as shown in FIG. 13, the transition detection circuit 105 outputs the transition detection signal S38 having a charging indication message to the charging and discharging switch circuit 100 to direct the charging and discharging switch circuit 100 to use the switching signal S37 as the charging control signal SCH, thereby charging the power stage circuit 12A to turn on the power transistor M1.

According to an embodiment of the present disclosure, during a switching period, each time when the transition detection circuit 105 detects a falling edge of the indication signal S39 as shown in FIG. 14, the transition detection circuit 105 outputs the transition detection signal S38 having a discharging indication message to the charging and discharging switch circuit 100 to direct the charging and discharging switch circuit 100 to use the switching signal S37 as the discharging control signal SDG, thereby discharging the power stage circuit 12A to turn off the power transistor M1. From the above descriptions, it can be seen that the indication signal S39 can represent an on and off state of the power transistor M1 during each switching period. In some embodiments, the transition detection circuit 105 is arranged inside the determination circuit 103, and the transition detection signal S38 is generated and outputted by the determination circuit 103. In some other embodiments, the transition detection circuit 105 is omitted, and the determination circuit 103 detects the rising edge and the falling edge of the indication signal S39 to generate and output the transition detection signal S38.

As shown in FIGS. 13 and 14, during a switching period, a time-varied curve of the real voltage difference VGS of the power transistor M1 may shift from a time-varied curve of an ideal voltage difference VGSTG. Referring to FIG. 13, starting from a time point when the rising edge of the indication signal S39 occurs, the ideal voltage difference VGSTG takes an ideal time Tideal to increase from 0 volt to the power voltage VDD. Referring to FIG. 14, starting from a time point when the falling edge of the indication signal S39 occurs, the ideal voltage difference VGSTG also takes the ideal time Tideal to decrease from the power voltage VDD to 0 volt. According to this embodiment of the present disclosure, the power voltage VDD is divided evenly into m voltage sections. For example, the power voltage VDD is divided evenly into 3 voltage sections (m=3). Ideally, the real voltage difference VGS of the power transistor M1 is increased from 0 volt to one-third (⅓) of the power voltage VDD (a first target voltage) after one ideal interval time t0 has passed, is increased from one-third of the power voltage VDD to two-thirds (⅔) of the power voltage VDD (a second target voltage) after another ideal interval time t0 has passed, and is increased from two-thirds of the power voltage VDD to the power voltage VDD (a third target voltage) after yet another ideal interval time t0 has passed. It can therefore be seen that the ideal time Tideal is divided evenly into three ideal interval times t0, i.e., t0=Tideal/m, where m=3. Similarly, the real voltage difference VGS is ideally decreased from the power voltage VDD to two-thirds of the power voltage VDD, from two-thirds of the power voltage VDD to one-third of the power voltage VDD, and from one-third of the power voltage VDD to 0 volt, respectively, within three ideal interval times t0.

As the above descriptions, each time when the determination circuit enables the reset signal S35, the switch SW2 is turned on according to the enabled reset signal S35 (i.e., according to the pulse wave of the reset signal S35), so that the input capacitor Cin is discharged to zero voltage. Ideally, each time when the determination circuit enables the reset signal S35, the determination circuit 13 outputs the trigger signal S34 having an initial pulse wave P31, and the initial pulse wave P31 has a preset duty-on period DN31. In this embodiment, the preset duty-on period DN31 is equal to the ideal interval time t0 divided by a constant k (DN31=to/k). In an embodiment, the constant k is preset according to system requirements. In each ideal time Tideal, the trigger signal S34 has three initial pulse waves P31, which correspond to three ideal interval times t0, respectively. In FIGS. 13 and 14, the initial pulse waves P31 are presented with broken lines. Because some initial pulse waves P31 completely or partially overlap modulated pulse waves (e.g., modulated pulse waves P41-P43, modulated pulse waves P81-P83, etc., which would be described below), which are presented with solid lines, the broken lines of parts of the initial pulse waves P31 overlapping the modulated pulse waves are not shown in FIGS. 13 and 14.

However, during a switching period, the real voltage difference VGS of the power transistor M1 may actually reach at least one target voltage on time, early or late. Thus, the control circuit 10A of the embodiment of the preset disclosure adjusts the duty-on periods of the pulse waves of at least one of the charging control signal SCH and the discharging control signal SDG according to the real voltage difference VGS of the power transistor M1, so that the real voltage difference VGS approaches the ideal voltage difference VGSTG gradually.

Referring to FIG. 12, the determination circuit 103 also receives the indication signal S39. As shown in FIG. 13, based on the rising edge of the indication signal S39, the electronic circuit enters a current switching period, the charging and discharging switch circuit 100 uses the switching signal S37 as the charging control signal SCH according to the transition detection signal S38, and the gate capacitor voltage signal VCg enters the rising segment (i.e., the electronic circuit enters the charging period of the power stage circuit 12A), so that the real voltage difference VGS of the power transistor M1 is gradually increased as the gate capacitor voltage signal VCg. In particular, at a time point when the rising edge of the indication signal S39 occurs (i.e., a start time point of the first ideal interval time t0 during the charging period) and respective start time points of the second and third ideal interval times t0, the determination circuit 103 outputs the reset signal S35 having the pulse waves to turn on the switch SW2, thereby resetting the voltage of the input capacitor Cin to zero voltage. In this embodiment, it is assumed that the determination circuit 103 outputs the trigger signal S34 having the initial pulse waves P31 at respective start time points of the first to third ideal interval times t0. In other words, during the current switching period, the initial pulse waves P31 are used as the modulated pulse waves P41-P43 of the trigger signal S34 respectively, and a real duty-on periods Tvty(t) of each of the modulated pulse waves P41-P43 equals DN31 (=t0/k) (y is 41, 42 or 43) to turn on the switch SW1, so that the input capacitor Cin is charged, and the voltage level of the state signal Vstate starts increasing as the state signal Vstate presented with broken lines in FIG. 13. Based on the state signal Vstate in the current switching period, the charging control signal SCH has three initial pulse waves P60 in the first to third ideal interval times t0, respectively, by the operations of the comparator 101 and the charging and discharging switch circuit 100. It is assumed that, during the charging period of the current switching period, as shown in FIG. 13, the time-varied curve of the real voltage difference VGS shifts from the time-varied curve of the ideal voltage difference VGSTG based on the three initial pulse waves P60. From the above descriptions, it can be seen that the three initial pulse waves P60 correspond to the three initial pulse waves P31 of the trigger signal S34, respectively. The initial pulse waves P60 are presented with broken lines, and modulated pulse waves P61-P63 (which would be described below) are presented with solid lines. In FIG. 13, there should be three initial pulse waves P60, but the first initial pulse wave P60 is not shown in FIG. 13 because the first initial pulse wave P60 completely overlaps the modulated pulse wave P61.

Referring to FIG. 13, during the current switching period, starting from the start time point of the first ideal interval time t0, the real voltage difference VGS of the power transistor M1 takes a real interval time t11 equaling the ideal interval time t0 to increase from 0 volt to one-third of the power voltage VDD, i.e., t11=t0. Thus, a time difference Δt11 is obtained by subtracting the ideal interval time t0 from the real interval time t11 (Δt11=t11−t0=0, i.e., there is no error between the real interval time t11 and the ideal interval time t0). In an embodiment of the preset disclosure, as soon as the real voltage difference VGS reaches one-third of the power voltage VDD from 0 volt, the voltage level of the sensing voltage signal S30 equals the reference voltage V33. At this time, the comparison signal S33 outputted by the comparator 123 is switched to the high voltage level. The determination circuit 103 obtains the real interval time t11 according to the time point when the rising edge of the indication signal S39 occurs and a time point when the comparison signal S33 is switched to the high voltage level. The determination circuit 103 determines that the real interval time t11 equals the ideal interval time t0 (t11=t0), and calculates that the time difference Δt11 equals zero (Δt11=0).

The determination circuit 103 determines a real duty-on period of one of the modulated pulse waves of the trigger signal S34 in the next switching period according to a formula (1):

$$Tvty ( t + 1 ) = Tvty ( t ) + c ⋆ Δ tx \qquad ( 1 )$$

In the above formula (1), Tvty(t) represents the real duty-on period of one modulated pulse wave of the trigger signal S34 in the current switching period, Tvty(t+1) represents the real duty-on period of one modulated pulse wave of the trigger signal S34 in the next switching period, c is a predetermined error compensation coefficient, x is 11, 12, 13, 21, 22 or 23, and y is 41, 42, 43, 81, 82 or 83.

As the above descriptions, during the current switching period, the real duty-on period Tvt41(t) of the modulated pulse wave P41 of the trigger signal S34 equals DN31 (=t0/k), and Δt11=0. Thus, according to the formula (1), the determination circuit 103 determines that the real duty-on period Tvt41(t+1) of the modulated pulse wave P41 of the trigger signal S34 in the next switching period equals t0/k (that is, the preset duty-on period DN31), represented by Tvt41(t+1)=t0/k+c*0=t0/k=DN31. In this embodiment, the modulated pulse waves of the trigger signal S34 are presented with solid lines. Thus, the modulated pulse wave P41 in solid lines and the corresponding initial pulse wave P31 in broken lines overlap with each other, and only the modulated pulse wave P41 in solid lines is shown in FIG. 13.

According to the above descriptions, it is determined that the real duty-on period Tvt41 of the modulated pulse wave P41 equals the preset duty-on period DN31 of the initial pulse wave P31 for the next switching period. Thus, during the next switching period, the switch SW1 is turned on within the preset duty-on period DN31 according to the modulated pulse wave P41, and the input current provided by the input current source CUin charges the input capacitor Cin through the switch SW1 for a time length of the preset duty-on period DN31, so that, as shown in FIG. 13, a continuous period when a real voltage level of the state signal Vstate in solid lines is higher than the voltage level of the reference voltage signal Vsaw equals an ideal duty-on period (i.e., the duty-on period of the initial pulse wave P60). In such way, a continuous period when the switching signal S37 is at the high voltage level equals the ideal duty-on period. During the next switching period, when the charging and discharging switch circuit 100 outputs the switching signal S37 as the charging control signal SCH according to the transition detection signal S38 indicating the rising edge of the indication signal S39, the charging and discharging switch circuit 100 controls the duty-on period of the first pulse wave of the charging control signal SCH to equal the ideal duty-on period (that is, the duty-on period of the modulated pulse wave P61 equals the ideal duty-on period), so that the turn-on period of the power transistor M1 equals the ideal duty-on period.

Referring to FIG. 13, during the current switching period, starting from the start time point of the second ideal interval time t0, the real voltage difference VGS of the power transistor M1 takes a real interval time t12 to reach two-thirds of the power voltage VDD from one-third of the power voltage VDD with delay, and the real interval time t12 is greater than the ideal interval time t0, i.e., t12>t0. Thus, a time difference Δt12 is obtained by subtracting the ideal interval time t0 from the real interval time t12 (Δt12=t12−t0>0, i.e., there is an error between the real interval time t12 and the ideal interval time t0). In an embodiment of the preset disclosure, as soon as the real voltage difference VGS reaches two-thirds of the power voltage VDD from one-third of the power voltage VDD, the voltage level of the sensing voltage signal S30 equals the reference voltage V32. At this time, the comparison signal S32 outputted by the comparator 122 is switched to the high voltage level. The determination circuit 103 obtains the real interval time t12 according to the start time point of the second ideal interval time t0 and a time point when the comparison signal S32 is switched to the high voltage level. The determination circuit 103 determines that the real interval time t12 is greater than the ideal interval time t0 (t12>t0), and calculates that the time difference Δt12 is greater than zero (Δt12>0). As the above descriptions, during the current switching period, the real duty-on period Tvt42(t) of the modulated pulse wave P42 of the trigger signal S34 equals DN31 (=t0/k). According to the formula (1), the determination circuit 103 determines that the real duty-on period Tvt42(t+1) of the modulated pulse wave P42 of the trigger signal S34 in the next switching period equals t0/k+c*Δt12, that is, the real duty-on period Tvt42(t+1) is greater than the preset duty-on period DN31 (Tvt42(t+1)=t0/k+c*Δt12>DN31).

According to the above descriptions, it is determined that the real duty-on period Tvt42 of the modulated pulse wave P42 is greater than the preset duty-on period DN31 of the initial pulse wave P31 for the next switching period. Thus, during the next switching period, the switch SW1 is turned on within the longer real duty-on period Tvt42 according to the modulated pulse wave P42, and the input current provided by the input current source CUin charges the input capacitor Cin through the switch SW1 for a longer time (longer than the time length of the preset duty-on period DN31), so that, as shown in FIG. 13, the continuous period when the real voltage level of the state signal Vstate in solid lines is higher than the voltage level of the reference voltage signal Vsaw is elongated (longer than the ideal duty-on period). In such way, the continuous period when the switching signal S37 is at the high voltage level is elongated. During the next switching period, when the charging and discharging switch circuit 100 outputs the switching signal S37 as the charging control signal SCH based on the rising edge of the indication signal S39, the charging and discharging switch circuit 100 controls the duty-on period of the second pulse wave of the charging control signal SCH to be longer than the ideal duty-on period (that is, the duty-on period of the modulated pulse wave P62 is longer than the ideal duty-on period), so that the turn-on period of the power transistor M1 is elongated. Because the second initial pulse wave P60 and the modulated pulse wave P62 in solid lines are partially overlapped, broken lines of parts of the second initial pulse wave P60 overlapping the modulated pulse wave P62 are not shown in FIG. 13.

Referring to FIG. 13, during the current switching period, starting from the start time point of the third ideal interval time t0, the real voltage difference VGS of the power transistor M1 takes a real interval time t13 to early reach the power voltage VDD from two-thirds of the power voltage VDD, and the real interval time t13 is less than the ideal interval time t0, i.e., t13<t0. Thus, a time difference Δt13 is obtained by subtracting the ideal interval time t0 from the real interval time t13 (Δt13=t13−t0<0). In an embodiment of the preset disclosure, as soon as the real voltage difference VGS reaches the power voltage VDD from two-thirds of the power voltage VDD, the voltage level of the sensing voltage signal S30 equals the reference voltage V33. At this time, the comparison signal S31 outputted by the comparator 121 is switched to the high voltage level. The determination circuit 103 obtains the real interval time t13 according to the start time point of the third ideal interval time t0 and a time point when the comparison signal S31 is switched to the high voltage level. The determination circuit 103 determines that the real interval time t13 is less than the ideal interval time t0 (t13<t0), and calculates that the time difference Δt13 is smaller than zero (Δt13<0, i.e., there is an error between the real interval time t13 and the ideal interval time t0). As the above descriptions, during the current switching period, the real duty-on period Tvt43(t) of the modulated pulse wave P43 of the trigger signal S34 equals DN31 (=t0/k). According to the formula (1), the determination circuit 103 determines that the real duty-on period Tvt43(t+1) of the modulated pulse wave P43 of the trigger signal S34 in the next switching period equals t0/k+c*Δt13, that is, the real duty-on period Tvt43(t+1) is less than the preset duty-on period DN31 (Tvt43(t+1)=t0/k+c*Δt13<DN31).

According to the above descriptions, it is determined that the real duty-on period Tvt43 of the modulated pulse wave P43 is less than the preset duty-on period DN31 of the initial pulse wave P31 for the next switching period. Thus, during the next switching period, the switch SW1 is turned on within the shorter real duty-on period Tvt43 according to the modulated pulse wave P43, and the input current provided by the input current source CUin charges the input capacitor Cin through the switch SW1 for a shorter time (shorter than the time length of the preset duty-on period DN31), so that, as shown in FIG. 13, the continuous period when the real voltage level of the state signal Vstate in solid lines is higher than the voltage level of the reference voltage signal Vsaw is shortened (shorter than the ideal duty-on period). In such way, the continuous period when the switching signal S37 is at the high voltage level is shortened. During the next switching period, when the charging and discharging switch circuit 100 outputs the switching signal S37 as the charging control signal SCH based on the rising edge of the indication signal S39, the charging and discharging switch circuit 100 controls the duty-on period of the third pulse wave of the charging control signal SCH to be shorter than the ideal duty-on period (that is, the duty-on period of the modulated pulse wave P63 is shorter than the ideal duty-on period), so that the turn-on time of the power transistor M1 is shortened. Because the third initial pulse wave P60 and the modulated pulse wave P63 in solid lines are partially overlapped, broken lines of parts of the third initial pulse wave P60 overlapping the modulated pulse wave P63 are not shown in FIG. 13.

During each switching period, at an end time point of the third ideal interval time t0 of the charging period, the determination circuit 103 again outputs the reset signal S35 having the pulse wave to turn on the switch SW2, thereby again resetting the voltage of the input capacitor Cin to zero voltage. Meanwhile, at the end time point of the third ideal interval time t0, the charging and discharging switch circuit 100 outputs the charging control signal SCH having a pulse wave P64, and a pulse width period of the pulse wave P64 is ended at a time point when the falling edge of the indication signal S39 occurs. During the pulse width period of the pulse wave P64 (i.e., during the maintaining period of the power stage circuit 12A), the charging switch SW11 is constantly turned on according to the pulse wave P64, and the gate capacitor voltage signal VCg is increased and maintained at the peak level or the preset high level, so that the real voltage difference VGS of the power transistor M1 is increased and maintained at a specific level (this specific level is higher than the level of the power voltage VDD).

In an embodiment, during each switching period, the determination circuit 103 starts counting an amount of pulse waves of the reset signal S35 based on the rising edge of the indication signal S39. When the amount of pulse waves of the reset signal S35, which is accumulated from the time point when the rising edge of the indication signal S39 occurs, reaches a pulse wave amount threshold (e.g., 4(=m+1=3+1) as shown in FIG. 13), the determination circuit 103 outputs a control signal S40 to control the charging and discharging switch circuit 100, so that the charging control signal SCH outputted by the charging and discharging switch circuit 100 has the pulse wave P64.

As the above descriptions, the gate capacitor voltage signal VCg enters the rising segment based on the rising edge of the indication signal S39. During the period of the rising segment of the gate capacitor voltage signal VCg, the intermittent charging and discharging method of the preset disclosure adjusts the duty-on periods of the pulse waves of the charging control signal SCH (i.e., the turn-on time of the charging switch SW11) according to the real voltage difference VGS of the power transistor M1. In such way, the real voltage difference VGS of the power transistor M1 can gradually approach the ideal voltage difference VGSTG.

During each switching period, within the charging period and the maintaining period of the power stage circuit 12A, the charging and discharging switch circuit 100 controls the discharging control signal SDG to be maintained at the low voltage level to turn off the discharging switch SW13, thereby cutting off the discharging path between the node N10 and the ground terminal GND until the time point when the falling edge of the indication signal S39 occurs.

As shown in FIG. 14, during the above current switching period, based on the falling edge of the indication signal S39, the charging and discharging switch circuit 100 uses the switching signal S37 as the discharging control signal SDG according to the transition detection signal S38, and the gate capacitor voltage signal VCg enters the falling segment (i.e., the gate capacitor voltage signal VCg enters the discharging period of the power stage circuit 12A), so that the real voltage difference VGS of the power transistor M1 is gradually decreased as the gate capacitor voltage signal VCg. During the discharging period, the charging and discharging switch circuit 100 firstly controls the discharging control signal SDG to have a pulse wave P80 for turning on the discharging switch SW13 in the duty-on period of the pulse wave P80, so that the real voltage difference VGS of the power transistor M1 starts decreasing from the specific level higher than the power voltage VDD. The duty-on period of the pulse wave P80 is preset, specifically, the duty-on period of the pulse wave P80 begins at a time point when the real voltage difference VGS starts decreasing from the specific level and finishes at a time point of a first pulse wave of the reset signal S35 in the discharging period.

In addition, based on the falling edge of the indication signal S39, the charging and discharging switch circuit 100 controls the charging control signal SCH to switch to the low voltage level and then be maintained at the low voltage level until a time point when the rising edge of the indication signal S39 occurs in the next switching period.

Then, during the current switching period, at each of start time points of the first to third ideal interval times t0 in the discharging period, the determination circuit 103 outputs the reset signal S35 having one pulse wave to turn on the switch SW2, thereby resetting the voltage of the input capacitor Cin to zero voltage. In this embodiment, it is assumed that the determination circuit 103 outputs the trigger signal S34 having the initial pulse waves P31 at the respective start time points of the first to third ideal interval times t0 in the discharging period. In other words, during the current switching period, the initial pulse waves P31 are used as the modulated pulse waves P81-P83 of the trigger signal S34, and a real duty-on period Tvty(t) of each of the modulated pulse waves P81-P83 equals DN31 (=t0/k) (y is 81, 82 or 83). In addition, the determination circuit 103 outputs the trigger signal S34 having the initial pulse waves P31 at respective start time points of the first to third ideal interval times t0 in the discharging period to turn on the switch SW1, so that the input capacitor Cin is charged, and the voltage level of the state signal Vstate starts increasing as the state signal Vstate presented with broken lines in FIG. 14. Based on the state signal Vstate in the current switching period, the charging control signal SCH has three initial pulse waves P60 in the first to third ideal interval times t0, respectively, according to the operations of the comparator 101 and the charging and discharging switch circuit 100. During the discharging period of the current switching period, as shown in FIG. 14, the time-varied curve of the real voltage difference VGS shifts from the time-varied curve of the ideal voltage difference VGSTG based on the three initial pulse waves P60. From the above descriptions, it can be seen that the three initial pulse waves P60 in the discharging period correspond to the three initial pulse waves P31 of the trigger signal S34, respectively. The initial pulse waves P60 are presented with broken lines, and modulated pulse waves P91-P93 (which would be described below) are presented with solid lines.

Referring to FIG. 14, during the current switching period, starting from the start time point of the first ideal interval time t0, the real voltage difference VGS takes a real interval time t23 shorter than the ideal interval time t0 to early reach two-thirds of the power voltage VDD from the power voltage VDD, i.e., t23<t0. According to the above descriptions and operations similar to those in the charging period, the determination circuit 103 calculates that a time difference Δt23 is less than zero (Δt23=t23−t0<0, i.e., there is an error between the real interval time t23 and the ideal interval time t0). As the above descriptions, during the current switching period, the real duty-on period Tvt81(t) of the modulated pulse wave P81 of the trigger signal S34 equals DN31 (=t0/k). According to the formula (1), the determination circuit 103 determines that the real duty-on period Tvt81(t+1) of the modulated pulse wave P81 of the trigger signal S34 in the next switching period equals t0/k+c*Δt23, that is, the real duty-on period Tvt81(t+1) is less than the preset duty-on period DN31 (Tvt81(t+1)=t0/k+c*Δt23<DN31). The switch SW1 is turned on within the shorter real duty-on period Tvt81, and the input capacitor Cin is charged for a shorter time (shorter than the time length of the preset duty-on period DN31), so that, as shown in FIG. 14, the continuous period when the real voltage level of the state signal Vstate is higher than the voltage level of the reference voltage signal Vsaw is shortened (shorter than the ideal duty-on period). In such way, the continuous period when the switching signal S37 is at the high voltage level is shortened. During the next switching period, when the charging and discharging switch circuit 100 outputs the switching signal S37 as the discharging control signal SDG based on the falling edge of the indication signal S39, the charging and discharging switch circuit 100 controls the duty-on period of the first pulse wave of the discharging control signal SDG to be shorter than the ideal duty-on period (that is, the duty-on period of the modulated pulse wave P91 is shorter than the ideal duty-on period), so that the turn-on time of the power transistor M1 is shortened. Because the first initial pulse wave P60 and the modulated pulse wave P91 are partially overlapped, broken lines of parts of the first initial pulse wave P60 overlapping the modulated pulse wave P91 are not shown in FIG. 14.

Referring to FIG. 14, because a start time point of the duty-on period of the modulated pulse wave P91 overlaps an end time point of the duty-on period of the pulse wave P80, the rising edge of the modulated pulse wave P91 is not shown in FIG. 14.

Referring to FIG. 14, during the current switching period, starting from the start time point of the second ideal interval time t0, the real voltage difference VGS takes a real interval time t22 to reach one-third of the power voltage VDD from two-thirds of the power voltage VDD with delay, i.e., t22>t0. According to the above descriptions and operations similar to those in the charging period, the determination circuit 103 calculates that a time difference Δt22 is greater than zero (Δt22=t22−t0>0, i.e., there is an error between the real interval time t22 and the ideal interval time t0). As the above descriptions, during the current switching period, the real duty-on period Tvt82(t) of the modulated pulse wave P82 of the trigger signal S34 equals DN31 (=t0/k). According to the formula (1), the determination circuit 103 determines that the real duty-on period Tvt82(t+1) of the modulated pulse wave P82 of the trigger signal S34 in the next switching period equals t0/k+c*Δt22, that is, the real duty-on period Tvt82(t+1) is greater than the preset duty-on period DN31 (Tvt82(t+1)=t0/k+c*Δt22>DN31). The switch SW1 is turned on within the longer real duty-on period Tvt82, and the input capacitor Cin is charged for a longer time (longer than the time length of the preset duty-on period DN31), so that, as shown in FIG. 14, the continuous period when the real voltage level of the state signal Vstate is higher than the voltage level of the reference voltage signal Vsaw is elongated (longer than the ideal duty-on period). In such way, the continuous period when the switching signal S37 is at the high voltage level is elongated. During the next switching period, when the charging and discharging switch circuit 100 outputs the switching signal S37 as the discharging control signal SDG based on the falling edge of the indication signal S39, the charging and discharging switch circuit 100 controls the duty-on period of the second pulse wave of the discharging control signal SDG to be longer than the ideal duty-on period (that is, the duty-on period of the modulated pulse wave P92 is longer than the ideal duty-on period), so that the turn-on time of the power transistor M1 is elongated. Because the second initial pulse wave P60 and the modulated pulse wave P92 are partially overlapped, broken lines of parts of the second initial pulse wave P60 overlapping the modulated pulse wave P92 are not shown in FIG. 14.

Referring to FIG. 14, during the current switching period, starting from the start time point of the third ideal interval time t0, the real voltage difference VGS takes a real interval time t21 shorter than the ideal interval time t0 to early reach 0 volt from one-third of the power voltage VDD, i.e., t21<t0. According to the above descriptions and operations similar to those in the charging period, the determination circuit 103 calculates that a time difference Δt21 is less than zero (Δt21=t21−t0<0, i.e., there is an error between the real interval time t21 and the ideal interval time t0). As the above descriptions, during the current switching period, the real duty-on period Tvt83(t) of the modulated pulse wave P83 of the trigger signal S34 equals DN31 (=t0/k). According to the formula (1), the determination circuit 103 determines that the real duty-on period Tvt83(t+1) of the modulated pulse wave P83 of the trigger signal S34 in the next switching period equals t0/k+c*Δt21, that is, the real duty-on period Tvt83(t+1) is less than the preset duty-on period DN31 (Tvt83(t+1)=t0/k+c*Δt21<DN31). The switch SW1 is turned on within the shorter real duty-on period Tvt83, and the input capacitor Cin is charged for a shorter time (shorter than the time length of the preset duty-on period DN31), so that, as shown in FIG. 14, the continuous period when the real voltage level of the state signal Vstate is higher than the voltage level of the reference voltage signal Vsaw is shortened (shorter than the ideal duty-on period). In such way, the continuous period when the switching signal S37 is at the high voltage level is shortened. During the next switching period, when the charging and discharging switch circuit 100 outputs the switching signal S37 as the discharging control signal SDG based on the falling edge of the indication signal S39, the charging and discharging switch circuit 100 controls the duty-on period of the first pulse wave of the discharging control signal SDG to be shorter than the ideal duty-on period (that is, the duty-on period of the modulated pulse wave P93 is shorter than the ideal duty-on period), so that the turn-on time of the power transistor M1 is shortened. Because the third initial pulse wave P60 and the modulated pulse wave P93 are partially overlapped, broken lines of parts of the third initial pulse wave P60 overlapping the modulated pulse wave P93 are not shown in FIG. 14.

During each switching period, at an end time point of the third ideal interval time t0 of the discharging period, the determination circuit 103 again outputs the reset signal S35 having the pulse wave to turn on the switch SW2, thereby again resetting the voltage of the input capacitor Cin to zero voltage. Meanwhile, at the end time point of the third ideal interval time t0, the charging and discharging switch circuit 100 outputs the discharging control signal SDG having a pulse wave P94, and a pulse width period of the pulse wave P94 is ended at a time point when the rising edge of the indication signal S39 occurs. During the pulse width period of the pulse wave P94 (i.e., during the maintaining period of the power stage circuit 12A), the discharging switch SW13 is constantly turned on according to the pulse wave P94, and the gate capacitor voltage signal VCg is maintained at the valley level or the preset low level, so that the real voltage difference VGS of the power transistor M1 is maintained at 0 volt.

In an embodiment, during each switching period, the determination circuit 103 starts counting an amount of pulse waves of the reset signal S35 based on the falling edge of the indication signal S39. When the amount of pulse waves of the reset signal S35, which is accumulated from the time point when the falling edge of the indication signal S39 occurs, reaches a pulse wave amount threshold (e.g., 4(=m+1=3+1) as shown in FIG. 14), the determination circuit 103 outputs a control signal S40 to control the charging and discharging switch circuit 100, so that the discharging control signal SDG outputted by the charging and discharging switch circuit 100 has the pulse wave P94.

As the above descriptions, the gate capacitor voltage signal VCg enters the falling segment based on the falling edge of the indication signal S39. During the period of the falling segment of the gate capacitor voltage signal VCg, the intermittent charging and discharging method of the preset disclosure adjusts the duty-on periods of the pulse waves of the discharging control signal SDG (i.e., the turn-on time of the discharging switch SW13) according to the real voltage difference VGS of the power transistor M1, so that the real voltage difference VGS of the power transistor M1 can gradually approach the ideal voltage difference VGSTG.

According to the above descriptions, during one current switching period, the control circuit 10A determines the pattern of the pulse waves of the charging control signal SCH and the discharging control signal SDG in the next switching period according to the real voltage difference VGS, thereby implementing the intermittent charging and discharging method of the preset disclosure to improve the accuracy of the charging and discharging control and further flexibly control the charging and discharging states of the power stage circuit 12A. By the charging and discharging control of the present disclosure, the time-varied curve of the real voltage difference VGS of the power transistor M1 can be changed to gradually match the time-varied curve of the ideal voltage difference VGSTG, so that the level change of the output voltage at the output terminal LIN of the power stage circuit 12A achieves an expected value.

In the above embodiments, the pattern of the pulse waves of the charging control signal SCH and/or the pattern of the pulse waves of the discharging control signal SDG is determined according to the real gate source voltage (VGS) of the power transistor M1. In other embodiments, the pattern of the pulse waves of the charging control signal SCH and/or the pattern of the pulse waves of the discharging control signal SDG can be determined according to a drain source voltage (VDS) of the power transistor M1. In particular, the control circuit 10A can perform operations similar to those in FIGS. 12-14 according to a condition where the drain source voltage of the power transistor M1 is decreased from the power voltage VBAT to 0 volt in the ideal time Tideal, to determine the pattern of the pulse waves of the charging control signal SCH and/or the pattern of the pulse waves of the discharging control signal SDG. Related descriptions thereof can be understood with reference to the descriptions of FIGS. 12-14, and thus are omitted herein.

Referring to FIG. 15, FIG. 15 is a circuit diagram of an electronic circuit 15 using intermittent charging and discharging in accordance with an eleventh embodiment of the present disclosure. In FIG. 5, the charging circuit 11A includes the current source CU1, and the discharging circuit 13A includes the current source CU2. In the embodiment of FIG. 15, the charging circuit 11B includes a charging-side resistor R15, which replaces the charging circuit 11A, and the discharging circuit 13B includes a discharging-side resistor R16, which replaces the discharging circuit 13A.

When the charging switch SW11 is turned on according to the charging control signal SCH, the charging current flows from the power voltage VCC and sequentially through the charging-side resistor R15 and the turned-on charging switch SW11 to the capacitor Cg, to charge the capacitor Cg, so that the voltage level of the gate capacitor voltage signal VCg at the first terminal of the capacitor Cg is gradually increased. When the discharging switch SW13 is turned on according to the discharging control signal SDG, the discharging current flows from the first terminal of the capacitor Cg and sequentially through the discharging-side resistor R16 and the turned-on discharging switch SW13 to the ground terminal GND, to discharge the capacitor Cg, so that the voltage level of the gate capacitor voltage signal VCg is gradually decreased.

In the above embodiments, based on the rising edge of the indication signal S39, the charging and discharging switch circuit 100 uses the switching signal S37 as only the charging control signal SCH according to the transition detection signal S38, and based on the falling edge of the indication signal S39, the charging and discharging switch circuit 100 uses the switching signal S37 as only the discharging control signal SDG according to the transition detection signal S38. In some embodiments, based on the rising edge and/or the falling edge of the indication signal S39, the charging and discharging switch circuit 100 uses the switching signal S37 as both the charging control signal SCH and the discharging control signal SDG according to the transition detection signal S38. For example, during the charging period, based on the rising edge of the indication signal S39, the charging and discharging switch circuit 100 uses the switching signal S37 as both the charging control signal SCH and the discharging control signal SDG, so that, as shown in FIG. 7, the pattern of the pulse waves of the charging control signal SCH is the same as the pattern of the pulse waves of the discharging control signal SDG.

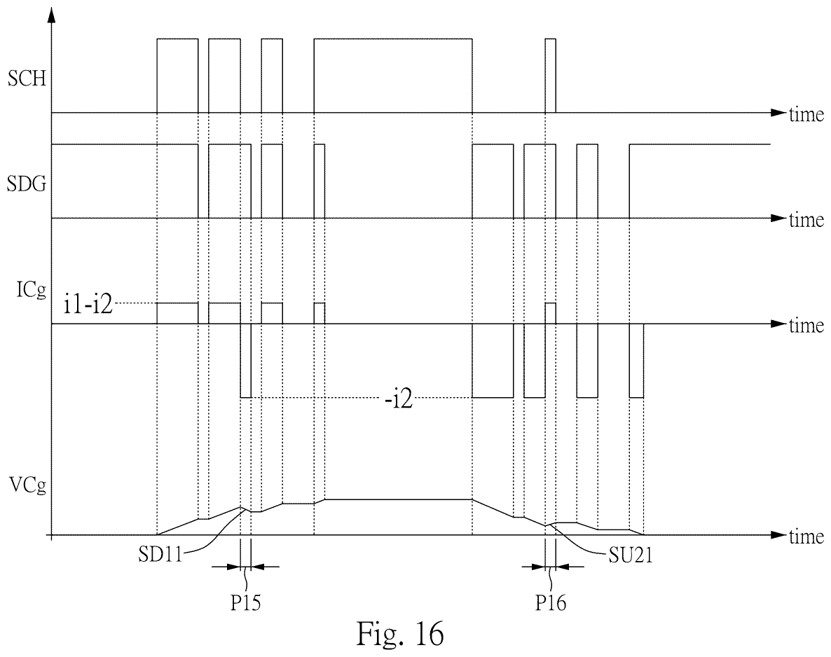

According to the above descriptions, during one current switching period, the control circuit 10A controls the charging circuit 11A and the discharging circuit 13A according to the switching signal S37 determined in the previous switching period, thereby controlling the charging and discharging of the power stage circuit 12A to control the turn-on and turn-off speeds of the power transistor M1. According to another embodiment of the present disclosure, during one charging period of the current switching period, while the power stage circuit 12A is charged based on the switching signal S37 determined in the previous switching period, the control circuit 10A determines whether to extra enable the discharging control signal SDG according to the real voltage difference VGS (that is, the control circuit 10A extra controls the discharging control signal SDG to be at the high voltage level). In particular, referring to FIGS. 12 and 13, during the charging period of one current switching period, the power stage circuit 12A is over charged when the determination circuit 103 determines that one of the comparison signals S31-S33 is switched to the high voltage level within the first ideal interval time t0, that the comparison signal S31 or S32 is switched to the high voltage level within the second ideal interval time t0, or that the comparison signal S31 is switched to the high voltage level within the period of first half (first ½) of the third ideal interval time t0. At this time, the determination circuit 103 controls the charging and discharging switch circuit 100 through a determination signal S36 to extra enable the discharging control signal SDG, thereby decreasing the voltage level of the gate capacitor voltage signal VCg. For example, referring to FIG. 16, during a period P15 of the charging period, the discharging control signal SDG is not switched to the low voltage level as in FIG. 7, but is maintained at the high voltage level (that is, the discharging control signal SDG is extra enabled in comparison to the corresponding pulse wave in FIG. 7, thereby elongating the duty-on period of the corresponding pulse wave of the discharging control signal SDG) to turn on the discharging switch SW13. Thus, the gate capacitor voltage signal VCg is decreased in the period P15, so that there is a discharging stepped-shape segment SD11 in the rising segment of the gate capacitor voltage signal VCg, thereby compensating for a fast rise in the level of the gate capacitor voltage signal VCg due to over-charge. As shown in FIG. 16, the discharging stepped-shape segment SD11 is between two charging stepped-shape segments.

Similarly, during one discharging period of the current switching period, while the power stage circuit 12A is discharged based on the switching signal S37 determined in the previous switching period, the control circuit 10A determines whether to extra enable the charging control signal SCH according to the real voltage difference VGS (that is, the control circuit 10A extra controls the charging control signal SCH to be at the high voltage level). In particular, referring to FIGS. 12 and 14, during the discharging period of one current switching period, the power stage circuit 12A is over discharged when the determination circuit 103 determines that the comparison signal S32 or the comparison signal S33 is switched to the low voltage level within the first ideal interval time t0, that the comparison signal S33 is switched to the low voltage level within the second ideal interval time t0, or that the comparison signal S33 is switched to the low voltage level within the period of first half (first ½) of the third ideal interval time t0. At this time, the determination circuit 103 controls the charging and discharging switch circuit 100 through the determination signal S36 to extra enable the charging control signal SCH, thereby increasing the voltage level of the gate capacitor voltage signal VCg. For example, referring to FIG. 16, during a period P16 of the charging period, the charging control signal SCH is not maintained at the low voltage level as in FIG. 7, but is switched to the high voltage level (that is, the charging control signal SCH is extra enabled in comparison to the embodiment of FIG. 7) to turn on the charging switch SW11. Thus, the gate capacitor voltage signal VCg is increased in the period P16, so that there is a charging stepped-shape segment SU21 in the falling segment of the gate capacitor voltage signal VCg, thereby compensating for a fast fall in the level of the gate capacitor voltage signal VCg due to over-discharge. As shown in FIG. 16, the charging stepped-shape segment SU21 is between two discharging stepped-shape segments. In this embodiment, the periods P15 and P16 have the same time length.

According to the embodiment of FIG. 16, during the current switching period, when the power stage circuit 12A is over charged or discharged based on the switching signal S37 determined in the previous switching period, the control circuit 10A can instantly trim the pattern of the pulse waves of the charging control signal SCH and/or the pattern of the pulse waves of the discharging control signal SDG, thereby modifying the level change of the gate capacitor voltage signal VCg to speed up matching the time-varied curve of the real voltage difference VGS of the power transistor M1 to the time-varied curve of the ideal voltage difference VGSTG.

In other embodiments, the control circuit 10A or the charging and discharging switch circuit 100 can further include a compensation circuit which receives the determination signal S36 and generates a pulse wave corresponding to the discharging stepped-shape segment SD11 and/or a pulse wave corresponding to the charging stepped-shape segment SU21 according to the determination circuit S36. The charging and discharging switch circuit 100 controls the discharging control signal SDG to have this pulse wave (e.g., the pulse wave of the discharging control signal SDG corresponding to the period P15 in FIG. 16) when receiving this pulse wave in the charging period. The charging and discharging switch circuit 100 controls the charging control signal SCH to have this pulse wave (e.g., the pulse wave of the charging control signal SCH corresponding to the period P16 in FIG. 16) when receiving this pulse wave in the discharging period. The present disclosure does not limit the structure of the compensation circuit, and any circuits capable of generating a pulse wave with fixed width according to the determination signal S36 can be used as the compensation circuit.

Notably, the intermittent charging and discharging method of the present disclosure achieves more accurate control by replacing the existing arts utilizing continuous charging in the charging period and continuous discharging in the discharging period. The electronic components included in the charging circuit, the discharging circuit and the power stage circuit of the electronic circuits using intermittent charging and discharging of the present disclosure are examples for illustrative purpose, and are not limited by the present disclosure.

In sum, the present disclosure provides an intermittent charging and discharging method, an intermittent discharging method and an electronic circuit using intermittent charging and discharging. The intermittent charging and discharging method and the electronic circuit using intermittent charging and discharging of the present disclosure apply intermittent control to on-off of both the charging circuit (the charging switch included therein) and the discharging circuit (the discharging switch included therein). The intermittent discharging method of the present disclosure applies intermittent control to on-off of the discharging circuit (the discharging switch included therein). Therefore, in comparison with the existing arts, the intermittent charging and discharging method, the intermittent discharging method and the electronic circuit using intermittent charging and discharging of the present disclosure greatly improve the accuracy of control. At the same time, in comparison with the existing arts, the electronic circuit using intermittent charging and discharging of the present disclosure requires less hardware for the control circuit, thereby achieving reducing both design area and power consumption to save cost.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the invention. In view of the foregoing, it is intended that the present invention cover modifications and variations of this invention provided they fall within the scope of the following claims.

What is claimed is:

1. An intermittent charging and discharging method, comprising:
during a first period, charging a power stage circuit multiple times respectively within a plurality of duty-on periods of a plurality of consecutive pulse waves of a charging control signal, to generate a plurality of first charging stepped-shape segments of a rising segment of a voltage signal of the power stage circuit; and
during the first period, stopping charging the power stage circuit within a plurality of duty-off periods of the plurality of consecutive pulse waves of the charging control signal, to generate a stopping charging horizontal segment or a first discharging stepped-shape segment between two of the plurality of first charging stepped-shape segments of the voltage signal.

2. The intermittent charging and discharging method of claim 1, further comprising:
setting the plurality of duty-on periods of the plurality of consecutive pulse waves of the charging control signal to be different from each other.

3. The intermittent charging and discharging method of claim 2, further comprising:
setting the plurality of duty-off periods of the plurality of consecutive pulse waves of the charging control signal to be different from each other.

4. The intermittent charging and discharging method of claim 1, further comprising:
setting the plurality of duty-on periods of the plurality of consecutive pulse waves of the charging control signal to be the same as each other; and
setting the plurality of duty-off periods of the plurality of consecutive pulse waves of the charging control signal to be different from each other.

5. The intermittent charging and discharging method of claim 1, further comprising:
during a second period after the first period, discharging the power stage circuit multiple times respectively within a plurality of duty-on periods of a plurality of consecutive pulse waves of a discharging control signal, to generate a plurality of second discharging stepped-shape segments of a falling segment in the voltage signal; and
during the second period, stopping discharging the power stage circuit within a plurality of duty-off periods of the plurality of consecutive pulse waves of the discharging control signal, to generate a stopping discharging horizontal segment or a second charging stepped-shape segment between two of the plurality of second discharging stepped-shape segments of the voltage signal.

6. The intermittent charging and discharging method of claim 1, wherein the power stage circuit comprises a power transistor and a capacitor, a first terminal of the power transistor is coupled to a power voltage, a second terminal of the power transistor is coupled to a ground terminal, a control terminal of the power transistor is coupled to an input terminal of the power stage circuit to receive the voltage signal, a first terminal of the capacitor is coupled to the control terminal of the power transistor, a second terminal of the capacitor is coupled to the ground terminal and is charged multiple times during the first period, and the plurality of duty-on periods of the plurality of consecutive pulse waves of the charging control signal are determined according to a voltage difference between the control terminal and the second terminal of the power stage circuit.

7. An intermittent discharging method, comprising:
discharging a power stage circuit multiple times respectively within a plurality of duty-on periods of a plurality of consecutive pulse waves of a discharging control signal, to generate a plurality of discharging stepped-shape segments of a falling segment in a voltage signal of the power stage circuit; and
stopping discharging the power stage circuit within a plurality of duty-off periods of the plurality of consecutive pulse waves of the discharging control signal, to generate a stopping discharging horizontal segment or a charging stepped-shape segment between two of the plurality of discharging stepped-shape segments of the voltage signal.

8. An electronic circuit using intermittent charging and discharging, comprising:
a control circuit, configured to generate a charging control signal;
a power stage circuit, configured to receive a voltage signal; and
a charging circuit, coupled to the power stage circuit and the control circuit, and controlled by the control circuit according to the charging control signal;
wherein during a first period, the control circuit controls the charging circuit to charge the power stage circuit multiple times respectively within a plurality of duty-on periods of a plurality of consecutive pulse waves of the charging control signal, to generate a plurality of first charging stepped-shape segments of a rising segment of the voltage signal, and
wherein during the first period, the control circuit controls the charging circuit to stop charging the power stage circuit within a plurality of duty-off periods of the plurality of consecutive pulse waves of the charging control signal, to generate a stopping charging horizontal segment or a first discharging stepped-shape segment between two of the plurality of first charging stepped-shape segments of the voltage signal.

9. The electronic circuit using intermittent charging and discharging of claim 8, wherein the control circuit is further configured to generate a discharging control signal, and the electronic circuit using intermittent charging and discharging further comprises:
a discharging circuit, coupled to the power stage circuit and the control circuit and controlled by the control circuit according to the discharging control signal;
wherein during a second period after the first period, the control circuit controls the charging circuit to discharge the power stage circuit multiple times respectively within a plurality of duty-on periods of a plurality of consecutive pulse waves of the discharging control signal, to generate a plurality of second discharging stepped-shape segments of a falling segment in the voltage signal, and
wherein during the second period, the control circuit controls the charging circuit to stop discharging the power stage circuit within a plurality of duty-off periods of the plurality of consecutive pulse waves of the discharging control signal, to generate a stopping discharging horizontal segment or a second charging stepped-shape segment between two of the plurality of second discharging stepped-shape segments of the voltage signal.

10. The electronic circuit using intermittent charging and discharging of claim 9, wherein the discharging circuit comprises:
a discharging-side current source circuit, coupled to the power stage circuit; and
a discharging switch, wherein a first terminal of the discharging switch is coupled to the discharging-side current source circuit, a second terminal of the discharging switch is coupled to a ground terminal, and a control terminal of the discharging switch is coupled to the control circuit to receive the discharging control signal, and
wherein when the discharging switch is turned on according to the discharging control signal, the discharging-side current source circuit provides a discharging current towards the ground terminal through the discharging switch, to discharge the power stage circuit.

11. The electronic circuit using intermittent charging and discharging of claim 9, wherein the power stage circuit comprises:
a first capacitor, wherein a first terminal of the first capacitor is coupled to the charging circuit and the discharging circuit at an input terminal of the power stage circuit, and a second terminal of the first capacitor is coupled to a ground terminal; and
a power transistor, wherein a first terminal of the power transistor is coupled to a first power voltage, a second terminal of the power transistor is coupled to the ground terminal, and a control terminal of the power transistor is coupled to the input terminal.

12. The electronic circuit using intermittent charging and discharging of claim 11, wherein the power stage circuit further comprises:
a first resistor, wherein a first terminal of the first resistor is coupled to the first power voltage, and a second terminal of the first resistor is coupled to an output terminal of the power stage circuit;
a second capacitor, wherein a first terminal of the second capacitor is coupled to the output terminal, and a second terminal of the second capacitor is coupled to the ground terminal;
a second resistor, wherein a first terminal of the second resistor is coupled to the first power voltage;
an upper side diode, wherein an anode terminal of the upper side diode is coupled to a second terminal of the second resistor, and a cathode terminal of the upper side diode is coupled to the output terminal; and
a lower side diode, wherein an anode terminal of the lower side diode is coupled to the output terminal, and a cathode terminal of the lower side diode is coupled to the first terminal of the power transistor.

13. The electronic circuit using intermittent charging and discharging of claim 8, wherein the charging circuit comprises:
a charging-side current source circuit; and
a charging switch, wherein a first terminal of the charging switch is coupled to the charging-side current source circuit, a second terminal of the charging switch is coupled to the power stage circuit, and a control terminal of the charging switch is coupled to the control circuit to receive the charging control signal, and
wherein when the charging switch is turned on according to the charging control signal, the charging-side current source circuit provides a charging current flowing to the power stage circuit through the charging switch, to charge the power stage circuit.

14. The electronic circuit using intermittent charging and discharging of claim 11, wherein the control circuit comprises:
a first comparator, wherein a first input terminal of the first comparator receives a first reference voltage signal, a second input terminal of the first comparator receives a state signal, the first comparator compares the first reference voltage signal and the state signal to generate a switching signal at an output terminal of the first comparator, and wherein the state signal represents an altered state of a voltage difference between the control terminal and the second terminal of the power transistor; and
an output circuit, configured to receive the switching signal and to output the switching signal as the charging control signal or the discharging control signal.

15. The electronic circuit using intermittent charging and discharging of claim 14, wherein the control circuit further comprises:
a sensing comparison circuit, configured to receive a sensing voltage signal and compare the sensing voltage signal with a plurality of second reference voltages to output a plurality of comparison signals, wherein the sensing voltage signal represents the voltage difference of the power transistor;
a determination circuit, configured to receive the plurality of comparison signals and determine a time difference between a time taken by the sensing voltage signal to reach each of the plurality of second reference voltages and a time threshold, to generate a trigger signal; and
a signal generation circuit, configured to receive the trigger signal, generate the state signal, and control a level of the state signal according to the trigger signal.

16. The electronic circuit using intermittent charging and discharging of claim 15, wherein the sensing comparison circuit comprises:
a sensing circuit, configured to sense the voltage difference of the power transistor to output the sensing voltage signal; and
a plurality of second comparators, wherein a first input terminal of each of the plurality of second comparators is coupled to the sensing circuit to receive the sensing voltage signal, a plurality of second input terminals of the plurality of second comparators are coupled to the plurality of second reference voltages respectively, and a plurality of output terminals of the plurality of second comparators output the plurality of comparison signals respectively.

17. The electronic circuit using intermittent charging and discharging of claim 16, wherein the sensing comparison circuit further comprises:
a plurality of reference resistors, wherein the plurality of reference resistors are connected in series between a second power voltage and the ground terminal;
wherein the second power voltage is one of the plurality of second reference voltages, and
wherein the plurality of reference resistors comprises a first reference resistor and a second reference resistor, and a voltage at a common node of the first reference resistor and the second reference resistor is another one of the plurality of second reference voltages.

18. The electronic circuit using intermittent charging and discharging of claim 15, wherein the signal generation circuit comprises:
a first switch, wherein a first terminal of the first switch is coupled to the second input terminal of the first comparator at a first node, and a control terminal of the first switch receives the trigger signal;
an input current source, wherein a first terminal of the input current source is coupled to a second terminal of the first switch, and a second terminal of the input current source is coupled to the ground terminal, and wherein when the first switch is turned on according to the trigger signal, the input current source provides a current to the first node through the first switch; and
an input capacitor, wherein a first terminal of the input capacitor is coupled to the first node, and a second terminal of the input capacitor is coupled to the ground terminal.

19. The electronic circuit using intermittent charging and discharging of claim 18, wherein the signal generation circuit further comprises:
a second switch, wherein a first terminal of the second switch is coupled to the first node, and a second terminal of the second switch is coupled to the ground terminal;
wherein the determination circuit generates a reset signal, and a control terminal of the second switch receives the reset signal, and
wherein the determination circuit enables the reset signal to turn on the second switch at every interval time which equals the time threshold.

20. The electronic circuit using intermittent charging and discharging of claim 14, wherein an on and off state of the power transistor of the power stage circuit is controlled by the voltage signal, an indication signal represents the on and off state of the power transistor, and the control circuit further comprises:
a transition detection circuit, configured to receive the indication signal and detect a rising edge and a falling edge of the indication signal to output a transition detection signal;
wherein when the transition detection circuit detects the rising edge of the indication signal, the transition detection circuit outputs the transition detection signal to control the output circuit to output the switching signal as the charging control signal, and
wherein when the transition detection circuit detects the falling edge of the indication signal, the transition detection circuit outputs the transition detection signal to control the output circuit to output the switching signal as the discharging control signal.
